(19) United States
(12) Patent Application Publication
(10) Pub. No.: US 2025/0160064 A1
(43) Pub. Date: May 15, 2025

(54) LIGHT EMITTING ELEMENT, DISPLAY DEVICE AND METHOD FOR MANUFACTURING THE SAME

(71) Applicant: Samsung Display Co., LTD., Yongin-si (KR)

(72) Inventor: Ki Chang EOM, Yongin-si (KR)

(21) Appl. No.: 18/889,821

(22) Filed: Sep. 19, 2024

(30) Foreign Application Priority Data
Nov. 9, 2023 (KR) 10-2023-0154084

(51) Int. Cl. H01L 33/38; H01L 25/16; H01L 33/00; H01L 33/20; H01L 33/62

(52) U.S. Cl. CPC H10H 20/831; H01L 25/167; H10H 20/018; H10H 20/857; H10H 20/032; H10H 20/0364; H10H 20/819

(57) ABSTRACT

A light emitting element, a display device, a method of manufacturing a light emitting element, and a method of manufacturing a display device are provided. The light emitting element includes a first portion including a first contact electrode, a first semiconductor layer, an active layer, and a second semiconductor layer arranged in a sequence, a second portion including a second contact electrode, a second semiconductor layer, and a third semiconductor layer arranged in a sequence, and a protective layer on a top portion and a side of the first portion and on a top portion and a side of the second portion, the first portion is on the second portion, and a diameter of the first portion may be smaller than a diameter of the second portion.

### CROSS-REFERENCE TO RELATED APPLICATION

The present application claims priority to and the benefit of Korean Patent Application No. 10-2023-0154084, filed on Nov. 9, 2023, in the Korean Intellectual Property Office, the entire disclosure of which is incorporated by reference herein.

### BACKGROUND

### 1. Field

The present disclosure relates to a light emitting element, a display device, and a method for manufacturing the same.

### 2. Description of the Related Art

With the development of the information society, the demand for display devices for displaying images is increasing in various forms. The display device may be a flat panel display such as a liquid crystal display, a field emission display, a light emitting display, and/or the like. The light emitting display device may include an organic light emitting display device including an organic light emitting diode (OLED) element as a light emitting element, and a miniature light emitting display device including a micro light emitting diode element (hereinafter referred to as a micro light emitting element) as a light emitting element.

In the manufacturing of ultra-small light emitting display devices, micro light emitting elements are contacted without a separate electrode between the common electrode and the light emitting element, which may cause resistance problems.

### SUMMARY

Aspects and features of embodiments of the present disclosure provide a vertical light emitting element including a first contact electrode in contact with a pixel electrode and a first contact electrode in contact with a common electrode, and the pixel electrode and the common electrode are located vertically with the light emitting element interposed between them, thereby providing a display device capable of easily supporting high resolution and a method of manufacturing the same.

However, aspects of the present disclosure are not limited to the one set forth herein. The above and other aspects of the present disclosure will become more apparent to one of ordinary skill in the art to which the present disclosure pertains by referencing the detailed description of the present disclosure given below.

According to one or more embodiments, a display panel that includes a light emitting element including a first portion including a first contact electrode, a first semiconductor layer, an active layer, and a second semiconductor layer arranged in a sequence, a second portion including a second contact electrode, a second semiconductor layer, and a third semiconductor layer arranged in a sequence, and a protective layer on a top portion and a side of the first portion and on a top portion and a side surface of the second portion, wherein the first portion is on the second portion, wherein a diameter of the first portion is smaller than a diameter of the second portion.

In one or more embodiments, the second semiconductor layer of the second portion is connected to the second semiconductor layer of the first portion.

In one or more embodiments, the first portion and the second portion have a cylindrical shape, wherein the second portion is around the first portion in a plane view.

In one or more embodiments, the second contact electrode is around the first portion in a plan view.

In one or more embodiments, the first portion and the second portion have a rectangular parallelepiped shape, wherein one side of the first portion and one side of the second portion are aligned and coincide with each other.

According to one or more embodiments, a display device includes a substrate, a common electrode on the substrate, an organic pattern layer on the common electrode, a light emitting element on the organic pattern layer and having a first contact electrode and a second contact electrode, a pixel electrode on the first contact electrode and a connection electrode connecting the second contact electrode and the common electrode, wherein the light emitting element includes, a first portion including the first contact electrode, a first semiconductor layer, an active layer, and a second semiconductor layer, a second portion including the second contact electrode, a second semiconductor layer, and a third semiconductor layer, and a protective layer on a top portion and a side of the first portion and a top portion and a side of the second portion, wherein the first portion is on the second portion, wherein a diameter of the first portion is smaller than a diameter of the second portion.

In one or more embodiments, the display device further includes an organic layer covering a top surface of the connection electrode and a side surface of the light emitting element.

In one or more embodiments, the connection electrode has a higher reflectivity than the pixel electrode.

In one or more embodiments, the common electrode and the connection electrode include a metal material, wherein the pixel electrode includes a transparent conductive oxide.

In one or more embodiments, the common electrode is a common layer that is common to a plurality of sub-pixels.

In one or more embodiments, the second semiconductor layer of the second portion is connected to the second semiconductor layer of the first portion.

In one or more embodiments, the first portion and the second portion have a cylindrical shape, the second portion is around the first portion in a plan view, the second contact electrode is around the first portion in a plan view.

In one or more embodiments, the display device of claim further includes a first organic layer covering the second contact electrode, a second organic layer on the first organic layer, a function layer between the first organic layer and the second organic layer, wherein the function layer includes at least one of a protective layer including an inorganic film or a reflective layer including a highly reflective material.

In one or more embodiments, the first portion and the second portion have a rectangular parallelepiped shape, wherein one side of the first portion and one side of the second portion are aligned and coincide with each other.

According to one or more embodiments, a method of manufacturing a light emitting element includes forming a plurality of semiconductor material layers on a base substrate, etching the plurality of semiconductor material layers to form a light emitting element including a third semiconductor layer, a second semiconductor layer, an active layer, and a first semiconductor layer, forming a first portion and a second portion of the light emitting element by etching a portion of the first semiconductor layer, the active layer, and the second semiconductor layer, forming a protective layer on a top portion and a side of the first portion and on a top portion and a side of the second portion, and forming a first contact electrode on a top of the first portion and forming a second contact electrode on a top of the second portion, wherein the second portion is on the first portion, and a diameter of the first portion is smaller than a diameter of the second portion.

In one or more embodiments, in the forming the first portion and the second portion, wherein a periphery of each of the first semiconductor layer, the active layer, and the second semiconductor layer is etched so that the first portion is at a center of the second portion in a plan view, so that a top surface of the first portion exposes the second semiconductor layer.

In one or more embodiments, in the forming the first contact electrode on the top surface of the first portion, and forming the second contact electrode on the top surface of the second portion, wherein the first contact electrode is formed to contact the first semiconductor layer of the first portion, wherein the second contact electrode is formed to contact the second semiconductor layer of the second portion.

According to the method of manufacturing a display device includes forming a thin film transistor layer and a common electrode on a substrate, forming a temporary adhesive layer on the common electrode and aligning light emitting elements, fixing a light emitting element from among the light emitting elements on the temporary adhesive layer and removing a portion of the temporary adhesive layer to form an organic pattern layer, forming a connection electrode connecting the common electrode and a second contact electrode of the light emitting element, forming an organic layer covering a portion of the connection electrode and the light emitting element, and forming a pixel electrode on a first contact electrode of the light emitting element, wherein the light emitting element includes, a first portion including the first contact electrode, a first semiconductor layer, an active layer, and a second semiconductor layer arranged in a sequence, a second portion including a second contact electrode, a second semiconductor layer, and a third semiconductor layer arranged in a sequence, wherein the first portion is on the second portion, wherein a diameter of the first portion is smaller than a diameter of the second portion.

In one or more embodiments, the fixing the light emitting element to the organic pattern layer further includes, curing the organic pattern layer at a first temperature, inserting a portion of the light emitting element into the organic pattern layer, and curing the organic pattern layer at a second temperature higher than the first temperature.

In one or more embodiments, the method further includes forming a light blocking layer on a via layer fixed to the organic pattern layer and defining a light emitting area, forming a first wavelength conversion layer in a region corresponding to a first sub-pixel, forming a second wavelength conversion layer in a region corresponding to a second sub-pixel, and forming a light transmitting layer in a region corresponding to a third sub-pixel from among the regions partitioned by the light blocking layer, and forming a first color filter on the first wavelength conversion layer, forming a second color filter on the second wavelength conversion layer, and the forming a third color filter on the light transmitting layer.

According to one or more embodiments, the display device, and the method of manufacturing the same according to one or more embodiments, the contact resistance between the pixel electrode and the common electrode and the light emitting element may be reduced.

However, the effects, aspects, and features of the present disclosure are not limited to the aforementioned effects, aspects, and features, and various other effects, aspects, and features are included in the present disclosure.

### BRIEF DESCRIPTION OF DRAWINGS

FIG. 1 is a perspective view illustrating a display device according to one or more embodiments.

FIG. 2 is a layout diagram illustrating a display device according to one or

more embodiments.

FIG. 3 is a block diagram illustrating a display device according to one or more embodiments.

FIG. 4 is an equivalent circuit diagram illustrating a sub-pixel according to one or more embodiments.

FIG. 5 is an equivalent circuit diagram illustrating a sub-pixel according to one or more embodiments.

FIG. 6 is a perspective view illustrating a structure of a light emitting element according to one or more embodiments.

FIG. 7 is a cross-sectional view illustrating a structure of a light emitting element according to one or more embodiments.

FIG. 8 is a layout diagram illustrating pixels of a display area according to one or more embodiments.

FIG. 9 is a cross-sectional view illustrating one example of a cross-section of display panel corresponding to the line 11-11′ of FIG. 8.

FIG. 10 is a cross-sectional view illustrating one example of an area A of FIG. 9 in detail.

FIG. 11 is a cross-sectional view illustrating another example of a cross-section of the display panel corresponding to line 11-11′ of FIG. 8.

FIG. 12 is a cross-sectional view illustrating one example of an area B of FIG. 11 in detail.

FIG. 13 is a perspective view illustrating the structure of a light emitting element according to one or more embodiments.

FIG. 14 is a cross-sectional view illustrating the structure of a light emitting element according to one or more embodiments.

FIG. 15 is a layout diagram illustrating pixels of a display area according to one or more embodiments.

FIG. 16 is a cross-sectional view illustrating one example of a cross-section of a display panel corresponding to the line 12-12′ of FIG. 15.

FIG. 17 is a cross-sectional view illustrating one example of an area C of FIG. 16 in detail.

FIG. 18 is a flowchart illustrating a method of manufacturing a light emitting element according to one or more embodiments.

FIGS. 19-24 are cross-sectional views to illustrate a method of manufacturing a light emitting element according to one or more embodiments.

FIG. 25 is a flowchart illustrating a method of manufacturing a display device according to one or more embodiments.

FIGS. 26-36 are cross-sectional views to illustrate a method of manufacturing a display device according to one or more embodiments.

FIG. 37 is an example diagram schematically showing a virtual reality device including a display device according to one or more embodiments;

FIG. 38 is an example diagram schematically showing a smart device including a display device according to one or more embodiments;

FIG. 39 is a diagram of an example schematically showing a vehicle including a display device according to one or more embodiments; and

FIG. 40 is a diagram of an example schematically showing a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “spaced from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the present disclosure and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, specific embodiments will be described with reference to the accompanying drawings.

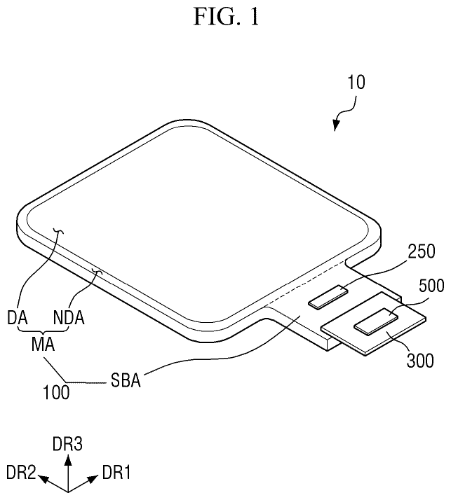

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and/or ultra mobile PCs (UMPC), as well as display screens for a variety of products such as televisions, laptops, monitors, billboards, and/or the internet of things (IoT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, a micro light emitting diode referred to as a light emitting element in the following for convenience of explanation.

The display device 10 includes a display panel 100, a display driving circuit 250, a circuit board 300, and a power supply circuit 500.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be formed to be flexible, such as to be able to be bent, curved, bent, folded, and/or rolled.

The substrate SUB of the display panel 100 may include a main area MA and a sub-area SBA.

The main area MA may include a display area DA that displays an image and a non-display area NDA that is a peripheral area of the display area DA and is around the display area DA along an edge or a periphery of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not limited thereto. For example, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board, or a chip on film (COF).

The power supply circuit 500 may generate a plurality of panel driving voltages according to an external power supply voltage. The power supply circuit 500 may be formed as an integrated circuit (IC) and attached to the circuit board 300 using a COF method.

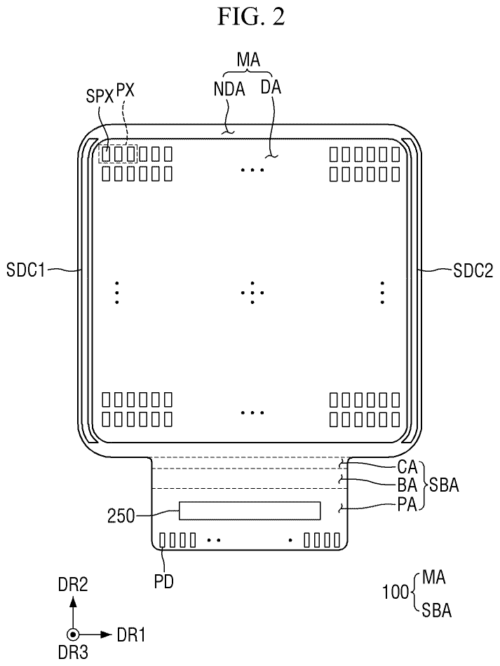

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit SDC1 and a second scan driving unit SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, it is not limited thereto. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub-area SBA is smaller than the length in the first direction DR1 of the main area MA or may be substantially equal to the length in the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

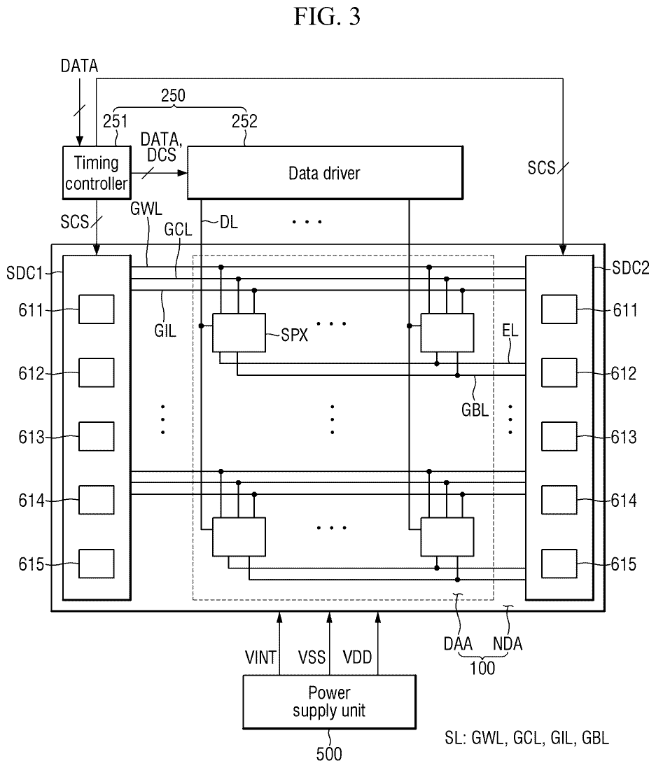

FIG. 3 is a block diagram illustrating a display device according to one or more embodiments.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of pixels PX may be arranged along rows and columns of a matrix along the first direction DR1 and the second direction DR2. The plurality of scan lines SL and the plurality of emission control lines EL may extend in the first direction DR1 and be arranged along the second direction DR2. The plurality of data lines DL may extend in the second direction DR2 and be arranged along the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light from the light emitting elements according to the data voltage.

The non-display area NDA includes a first scan driving unit SDC1, a second scan driving unit SDC2, and a display driving circuit 250.

Each of the first scan driving unit SDC1 and the second scan driving unit SDC2 may include a write scan signal output unit 611, a control scan signal output unit 612, an initialization scan signal output unit 613, a bias scan signal output unit 614, and a light emitting signal output unit 615. Each of the write scan signal output unit 611, the control scan signal output unit 612, the initialization scan signal output unit 613, the bias scan signal output unit 614, and the light emitting signal output unit 615 may receive a scan timing control signal SCS from the timing control circuit 400. The write scan signal output unit 611 may generate write scan signals according to the scan timing control signal SCS of the timing control circuit 400 and sequentially output them to the write scan lines GWL. The control scan signal output unit 612 may generate control scan signals according to the scan timing control signal SCS and sequentially output them to the control scan lines GCL. The initialization scan signal output unit 613 may generate initialization scan signals according to the scan timing control signal SCS and sequentially output them to the initialization scan lines GIL. The bias scan signal output unit 614 may generate bias scan signals according to the scan timing control signal SCS and sequentially output them to the bias scan lines EBL. The light emitting signal output unit 615 may generate light emitting control signals according to the scan timing control signal SCS and sequentially output them to the emission control lines EL.

The display driving circuit 250 includes a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data and timing signals from an external source. The timing control circuit 251 may generate the scan timing control signal SCS and the data timing control signal DCS to control the display panel 100 according to timing signals. The timing control circuit 400 may output the scan timing control signal SCS to the first scan driving unit SDC1 and the second scan driving unit SDC2. The timing control circuit 251 may output digital video data DATA and a data timing control signal DCS to the data driving circuit 252.

The power supply circuit 500 may generate a plurality of panel driving voltages according to an external power supply voltage. For example, the power supply circuit 500 may generate and supply a first driving voltage VDD, a second driving voltage VSS, and a third driving voltage VINT to the display panel 100.

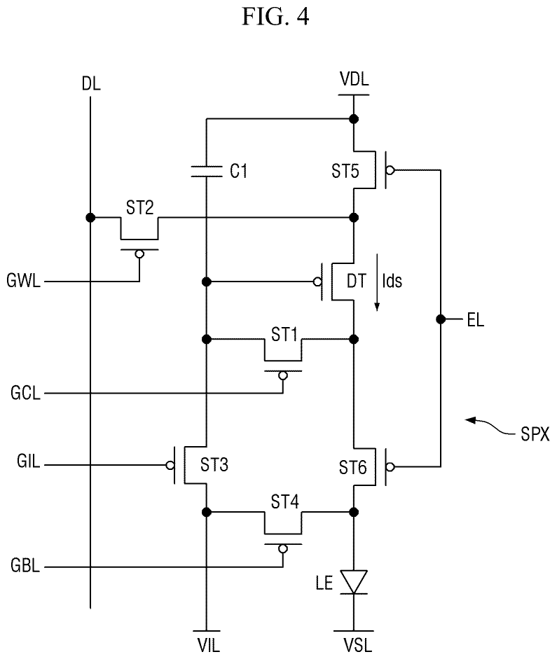

FIG. 4 is an equivalent circuit diagram illustrating a sub-pixel according to one or more embodiments.

Referring to FIG. 4, the sub-pixel SPX according to one or more embodiments may be connected to scan lines GWL, GIL, GCL, and GBL, an emission line EL, and a data line DL. For example, the sub-pixel SPX may be connected to the write scan line GWL, the initialization scan line GIL, the control scan line GCL, the bias scan line GBL, the emission line EL, and the data line DL.

The sub-pixel SPX according to one or more embodiments includes a driving transistor DT, switch elements, a capacitor C1, and a light emitting element LE. The switch elements include first to sixth transistors ST1, ST2, ST3, ST4, ST5, and ST6.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode. The light emitting element LE may be a micro light-emitting diode.

The light emitting element LE emits light according to the driving current Ids. The amount of light emitted from the light emitting element LE may be proportional to the driving current Ids. The anode electrode of the light emitting element LE may be connected to the first electrode of the fourth transistor ST4 and the second electrode of the sixth transistor ST6, and the cathode electrode may be connected to the second power supply line VSL to which the second power voltage is applied.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as P-type metal oxide semiconductor field effect transistor (MOSFET). In this case, the active layer of each of the first to sixth transistors ST1, ST2, ST3, ST4, ST5, and ST6 and the driving transistor DT may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. The gate electrodes of the fifth and sixth transistor ST5 and ST6 may be connected to the emission line EL. Because the first to sixth transistors ST1, ST2, ST3, ST4, ST5, and ST6 are formed as P-type MOSFET, they may be turned on when a scan signal of the gate low voltage and an emission signal of a low voltage are applied to the control scan line GCL, the initialization scan line GIL, the write scan line GWL, the bias scan line GBL, and the emission line EL, respectively. One electrode of the third transistor ST3 and one electrode of the fourth transistor ST4 may be connected to an initialization voltage line VIL.

For example, the first transistor ST1 may be connected between the second electrode and the gate electrode of the driving transistor DT. The second transistor ST2 may be connected between the data line DL and the first electrode of the driving transistor DT. The third transistor ST3 may be connected between the initialization voltage line VIL and the gate electrode of the driving transistor DT. The fourth transistor ST4 may be connected between the initialization voltage line VIL and the light emitting element LE. The fifth transistor ST5 may be connected between the first power supply line VDL and the first electrode of the driving transistor DT. The sixth transistor ST6 may be connected between the second electrode of the driving transistor DT and the light emitting element LE.

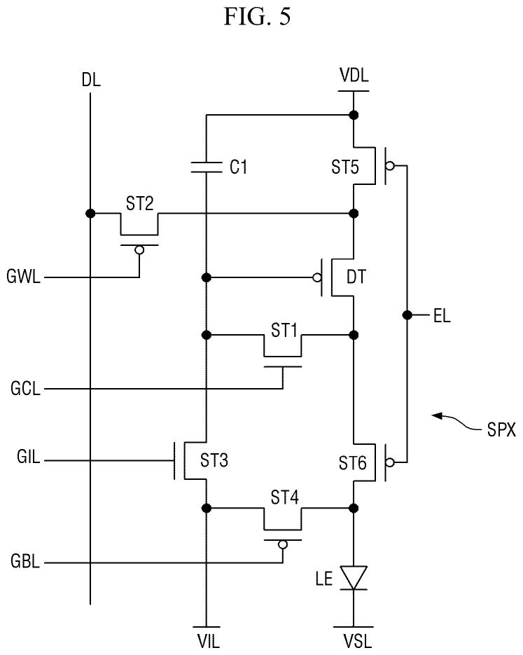

FIG. 5 is an equivalent circuit diagram illustrating a sub-pixel according to one or more embodiments.

Referring to FIG. 5, the driving transistor DT, the second transistor ST2, the fourth transistor ST4, the fifth transistor ST5, and the sixth transistor ST6 are formed of P-type MOSFET, and the first transistor ST1 and the third transistor ST3 may be formed as N-type MOSFET. The active layer of each of the driving transistor DT, the second transistor ST2, the fourth transistor ST4, the fifth transistor ST5, and the sixth transistor ST6 formed as the P-type MOSFET may be formed of polysilicon, and the active layer of each of the first transistor ST1 and the third transistor ST3 formed as the N-type MOSFET may be formed of the oxide semiconductor. In this case, transistors formed of polysilicon and transistors formed of oxide semiconductors may be arranged in different layers.

Because the first transistor ST1 and the third transistor ST3 are formed as N-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as P-type MOSFET, so they may be turned on when a scan signal with a gate low voltage and an emission signal with a low voltage are applied to the write scan line GWL, the bias scan line GBL, and the emission line EL, respectively.

Alternatively, the fourth transistor ST4 in FIG. 4 may be formed of the N-type MOSFET. In this case, the active layer of each fourth transistor ST4 may be formed of the oxide semiconductor. When the fourth transistor ST4 is formed of N-type MOSFET, it may be turned on when a bias scan signal of a gate high voltage is applied to the bias scan line GBL.

Alternatively, in one or more embodiments, the first to sixth transistors ST1, ST2, ST3, ST4, ST5, and ST6 and the driving transistor DT may all be formed as N-type MOSFET. In this case, the active layer of each of the first to sixth transistors ST1, ST2, ST3, ST4, ST5, and ST6 and the driving transistor DT may be formed of an oxide semiconductor.

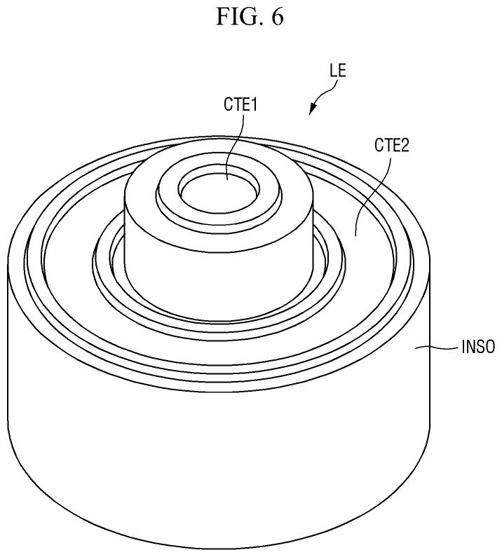

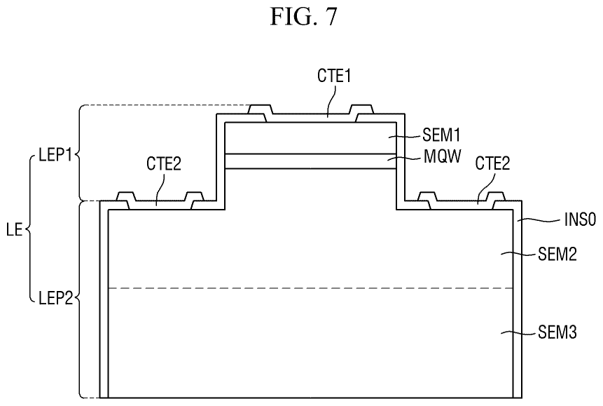

FIG. 6 is a perspective view illustrating the structure of a light emitting element according to one or more embodiments. FIG. 7 is a cross-sectional view illustrating the structure of a light emitting element according to one or more embodiments.

Referring to FIGS. 6 and 7, the light emitting element LE may be a vertical type micro LED extending in the third direction DR3. The vertical type micro LED refers to an LED having a structure in which a third semiconductor layer SEM3, a second semiconductor layer SEM2, an active layer MQW, and a first semiconductor layer SEM1 are sequentially arranged along the third direction DR3, which is the vertical direction.

Each of the plurality of light emitting elements LE may be formed of an inorganic material such as gallium nitride (GaN). Each of the plurality of light emitting elements LE may have a length in the first direction DR1, a length in the second direction DR2, and a length in the third direction DR3 of several to hundreds of μm. For example, each of the plurality of light emitting elements LE may have a length in the first direction DR1, a length in the second direction DR2, and a length in the third direction DR3 of approximately 100 μm or less.

Each of the plurality of light emitting elements LE may be formed by growing on a semiconductor substrate such as a silicon substrate and/or sapphire substrate.

The light emitting element LE may include a third semiconductor layer SEM3, a second semiconductor layer SEM2, an active layer MQW, a first semiconductor layer SEM1, a first contact electrode CTE1, a second contact electrode CTE2, and a protective layer INS0.

The third semiconductor layer SEM3 may include an undoped semiconductor and may be a material that is not doped as n-type or p-type. In one or more embodiments, a third semiconductor layer SEM3 may be at least one of undoped InAlGaN, GaN, AlGaN, InGaN, AlN, and/or InN, but is not limited thereto.

The second semiconductor layer SEM2 may be doped with a second conductivity type dopant such as Si, Ge, Sn, and/or the like. For example, the second semiconductor layer SEM2 may be n-GaN doped with n-type Si.

The active layer MQW may be disposed on the second semiconductor layer SEM2. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN or AlGaN but is not limited thereto. Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (e.g., light in the blue wavelength band) may be approximately 10 wt % to 20 wt %.

The first semiconductor layer SEM1 may be disposed on the active layer MQW. The first semiconductor layer SEM1 may be made of GaN doped with a first conductive dopant such as Mg, Zn, Ca, Se, Ba, and/or the like.

The electron blocking layer may be disposed between the first semiconductor layer SEM1 and the active layer MQW. The electron blocking layer may be a layer to suppress or prevent too many electrons from flowing into the active layer MQW. For example, the electron blocking layer may be AlGaN and/or p-AlGaN doped with p-type Mg. The electron blocking layer may be omitted.

The superlattice layer may be disposed between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

The light emitting element LE includes a first portion LEP1 and a second portion LEP2. The first portion LEP1 may be disposed on the second portion LEP2. In a plan view, the second portion LEP2 may be arranged to be around (e.g., to surround) the first portion LEP1.

The first portion LEP1 includes the first contact electrode CTE1, the first semiconductor layer SEM1, the active layer MQW, the second semiconductor layer SEM2, and the protective layer INS0. The second portion LEP2 includes the second contact electrode CTE2, the second semiconductor layer SEM2, the third semiconductor layer SEM3, and the protective layer INS0. The second semiconductor layer SEM2 of the first portion LEP1 may be connected to the second semiconductor layer SEM2 of the second portion LEP2. The diameter of the first portion LEP1 may be less than the diameter of the second portion LEP2. The second portion LEP2 that does not overlap the first portion LEP1 may be exposed to the outside.

The first contact electrode CTE1 may be disposed on the first semiconductor layer SEM1 of the first portion LEP1. The first contact electrode CTE1 may be disposed on the top surface of the first semiconductor layer SEM1.

The second contact electrode CTE2 may be disposed on the top surface of the second semiconductor layer SEM2 of the second portion LEP2 that does not overlap the first portion LEP1. In a plan view, the second contact electrode CTE2 may be disposed around the first portion LEP1.

The first contact electrode CTE1 and the second contact electrode CTE2 may include one of molybdenum (Mo), aluminium (Al), chromium (Cr), gold (Au), titanium (Ti), nickel (Ni), neodymium (Nd), and/or copper (Cu).

The protective layer INS0 may be disposed on the top surface of the first portion LEP1 and the second portion LEP2 where the first contact electrode CTE1 and the second contact electrode CTE2 are not disposed, and on the sides of the first portion LEP1 and the second portion LEP2. The protective layer INS0 may be a film to protect the side surface of the light emitting element LE. The protective layer INS0 may be formed of an inorganic film, such as a silicon nitride layer, a silicon oxynitride layer, a silicon oxide layer, a titanium oxide layer, and/or an aluminium oxide layer.

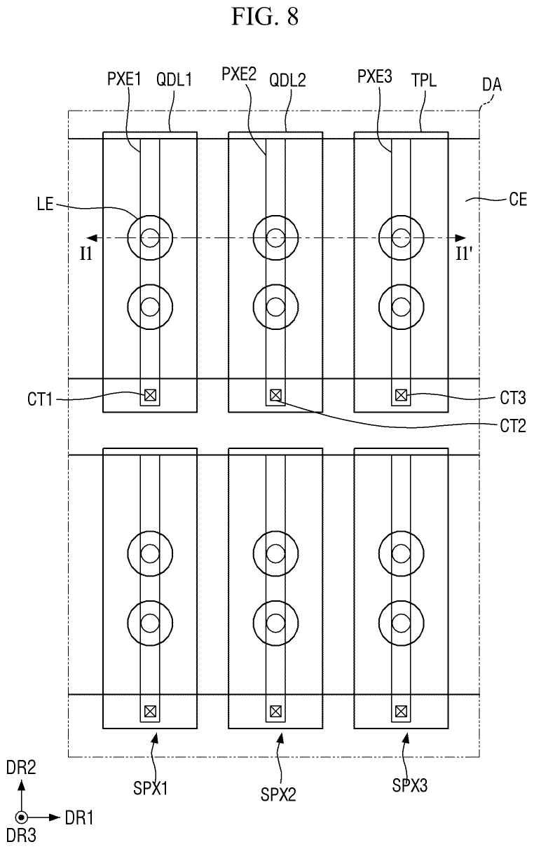

FIG. 8 is a layout diagram illustrating pixels of a display area according to one or more embodiments.

Referring to FIG. 8, each of the plurality of pixels PX in the display area DA may include a first sub-pixel SPX1, a second sub-pixel SPX2, and a third sub-pixel SPX3.

The plurality of pixels PX may be arranged in a matrix form. For example, the plurality of pixels PX may be arranged along rows and columns of a matrix. In each of the plurality of pixels PX, the first sub-pixel SPX1, the second sub-pixel SPX2, and the third sub-pixel SPX3 may be arranged along the first direction DR1.

The first sub-pixel SPX1 may emit light of a first color, the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may indicate that the main peak wavelength of the light is included in a wavelength band from approximately 370 μm to 460 μm, the green wavelength band may indicate that the main peak wavelength of the light is included in a wavelength band from approximately 480 μm to 560 μm, and the red wavelength band may indicate that the main peak wavelength of the light is included in a wavelength band from approximately 600 μm to 750 μm.

The first sub-pixel SPX1 includes a common electrode CE, a plurality of light emitting elements LE, a first pixel electrode PXE1, and a first light conversion layer QDL1. The second sub-pixel SPX2 includes a common electrode CE, a plurality of light emitting elements LE, a second pixel electrode PXE2, and a second light conversion layer QDL2. The third sub-pixel SPX3 includes a common electrode CE, a plurality of light emitting elements LE, a third pixel electrode PXE3, and a light transmitting layer TPL.

The common electrode CE may be a common layer commonly formed in the first sub-pixel SPX1, the second sub-pixel SPX2, and the third sub-pixel SPX3 arranged along the same first direction DR1.

The plurality of light emitting elements LE may have the same number of light emitting elements LE disposed in each sub-pixel. For example, two light emitting elements LE may be disposed in the first sub-pixel SPX1, the second sub-pixel SPX2, and the third sub-pixel SPX3. The plurality of light emitting elements LE may emit a third light, that is, light in the blue wavelength band. The plurality of light emitting elements LE may be circular in a plan view but are not limited thereto.

A pixel electrode PXE may be disposed on the light emitting elements LE included in each sub-pixel. Depending on the light conversion efficiency of the first light conversion layer QDL1 and the light conversion efficiency of the second light conversion layer QDL2, the area of the first sub-pixel SPX1, the area of the second sub-pixel SPX2, and the area of the third sub-pixel SPX3 may be set.

The first pixel electrode PXE1 may be electrically connected to the first electrode of the fourth transistor (ST4 in FIGS. 4 and 5) and the second electrode of the sixth transistor (ST6 in FIGS. 4 and 5) of the first sub-pixel SPX1 through a first connection hole CT1. The second pixel electrode PXE2 may be electrically connected to the first electrode of the fourth transistor (ST4 in FIGS. 4 and 5) and the second electrode of the sixth transistor (ST6 in FIGS. 4 and 5) of the second sub-pixel SPX2 through a second connection hole CT2. The third pixel electrode PXE3 may be electrically connected to the first electrode of the fourth transistor (ST4 in FIGS. 4 and 5) and the second electrode of the sixth transistor (ST6 in FIGS. 4 and 5) of the third sub-pixel SPX3 through a third connection hole CT3.

The first light conversion layer QDL1 may completely overlap the first pixel electrode PXE1 and the plurality of light emitting elements LE of the first sub-pixel SPX1. The area of the first light conversion layer QDL1 may be larger than the area of the first pixel electrode PXE1. The first light conversion layer QDL1 may convert or shift the peak wavelength of the incident light into light of another specific peak wavelength and emit it. For example, the first light conversion layer QDL1 may convert or shift the third light emitted from the plurality of light emitting elements LE of the first sub-pixel SPX1 into first light.

The second light conversion layer QDL2 may completely overlap the plurality of light emitting elements LE and the second pixel electrode PXE2 of the second sub-pixel SPX2. The area of the second light conversion layer QDL2 may be larger than the area of the second pixel electrode PXE2. The second light conversion layer QDL2 may convert or shift the peak wavelength of the incident light into light of another specific peak wavelength and emit it. For example, the second light conversion layer QDL2 may convert or shift the third light emitted from the plurality of light emitting elements LE of the second sub-pixel SPX2 into second light.

The light transmitting layer TPL may completely overlap the plurality of light emitting elements LE and the third pixel electrode PXE3 of the third sub-pixel SPX3. The light transmitting layer TPL may transmit incident light as it is. For example, the light transmitting layer TPL may directly transmit the third light emitted from the plurality of light emitting elements LE of the third sub-pixel SPX3.

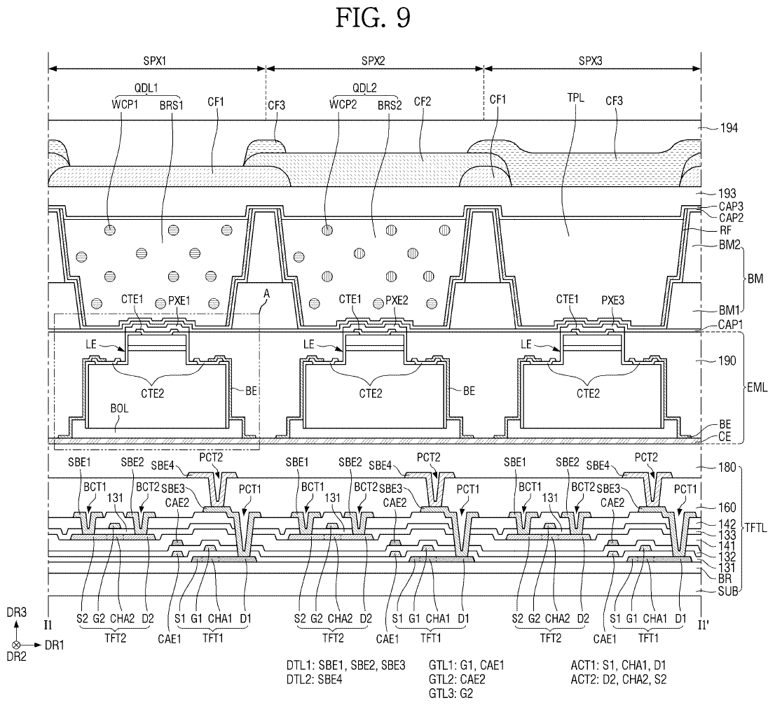

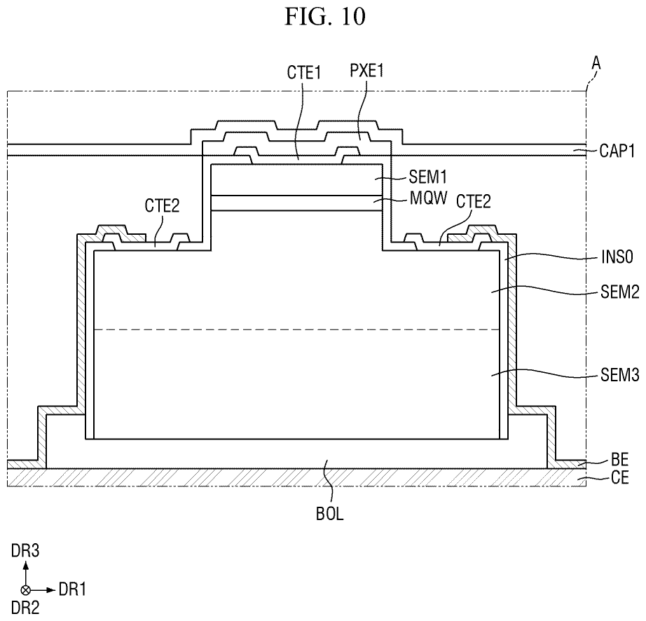

FIG. 9 is a cross-sectional view illustrating one example of a cross-section of display panel corresponding to the line 11-11′ of FIG. 8. FIG. 10 is a cross-sectional view illustrating one example of an area A of FIG. 9 in detail.

Referring to FIGS. 9 and 10, a substrate SUB may be made of an insulating material such as glass, polymer resin, and/or the like. If the substrate SUB is made of polymer resin, it may be a flexible substrate that may be stretched. The polymer resin may be acryl resin, epoxy resin, phenolic resin, polyamide resin, and/or polyimide resin.

A barrier film BR may be disposed on the substrate SUB. The barrier film BR is a membrane for protecting the transistors of a thin film transistor layer TFTL and the light emitting layer MQW of a light emitting element layer EML from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminium oxide layer.

A first thin film transistor TFT1 may be disposed on the barrier film BR. The first thin film transistor TFT1 may be either the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be disposed on the barrier film BR. The first active layer ACT1 of the first thin film transistor TFT1 may include polycrystalline silicon, single crystalline silicon, low-temperature polycrystalline silicon, and/or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate insulating film 131 may be disposed on the first channel area CHA1, the first source area S1, and the first drain area D1 of the first thin film transistor TFT1 and the barrier film BR. The first gate insulating film 131 may be formed of an inorganic film, for example, a silicon nitride layer, a silicon oxynitride layer, a silicon oxide layer, a titanium oxide layer, and/or an aluminium oxide layer.

A first gate metal layer GTL1 may be disposed on the first gate insulating film 131. The first gate metal layer GTL1 may include the first gate electrode G1 of the first thin film transistor TFT1 and a first capacitor electrode CAE1. The first gate electrode G1 may overlap the first active layer ACT1 in the third direction DR3. In FIG. 9, the first gate electrode G1 and the first capacitor electrode CAE1 are shown to be spaced from each other, but the first gate electrode G1 and the first capacitor electrode CAE1 may be connected to each other. The first gate metal layer GTL1 may be formed as a single layer or multiple layers of one of molybdenum (Mo), aluminium (Al), chromium (Cr), gold (Au), titanium (Ti), nickel (Ni), neodymium (Nd), and/or copper (Cu), and/or an alloy thereof.

A second gate insulating film 132 may be disposed on the first gate electrode G1 of the first thin film transistor TFT1, the first capacitor electrode CAE1, and the first gate insulating film 131. The second gate insulating film 132 may be formed of an inorganic film, for example, a silicon nitride layer, a silicon oxynitride layer, a silicon oxide layer, a titanium oxide layer, and/or an aluminium oxide layer.

A second gate metal layer GTL2 may be disposed on the second gate insulating film 132. The second gate metal layer GTL2 may include a second capacitor electrode CAE2. The second capacitor electrode CAE2 may overlap the first capacitor electrode CAE1 of the first thin film transistor TFT1 in the third direction DR3. Because the second gate insulating film 132 has a suitable permittivity (e.g., a predetermined permittivity), a capacitor (C1 in FIG. 5) may be formed by the first capacitor electrode CAE1, the second capacitor electrode CAE2, and the second gate insulating film 132 disposed between them. The second gate metal layer GTL2 may be formed as a single layer or multiple layers of any one of molybdenum (Mo), aluminium (Al), chromium (Cr), gold (Au), titanium (Ti), nickel (Ni), neodymium (Nd), and/or copper (Cu), and/or an alloy thereof.

A first interlayer insulating film 141 may be disposed on the second capacitor electrode CAE2 and the second gate insulating film 132. The first interlayer insulating layer 141 may be formed of an inorganic film, such as a silicon nitride layer, a silicon oxynitride layer, a silicon oxide layer, a titanium oxide layer, and/or an aluminium oxide layer.

A second thin film transistor TFT2 may be disposed on the first interlayer insulating film 141. The second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be disposed on the first interlayer insulating film 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn) and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be disposed on one side of the second channel area CHA2, and the second drain area D2 may be disposed on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate insulating film 133 may be disposed on the second active layer ACT2 of the second thin film transistor TFT2 and the first interlayer insulating film 141. The third gate insulating film 133 may be formed of an inorganic film, for example, a silicon nitride layer, a silicon oxynitride layer, a silicon oxide layer, a titanium oxide layer, and/or an aluminium oxide layer.

A third gate metal layer GTL3 may be disposed on the third gate insulating film 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers of one of molybdenum (Mo), aluminium (Al), chromium (Cr), gold (Au), titanium (Ti), nickel (Ni), neodymium (Nd), and/or copper (Cu), or an alloy thereof.

A second interlayer insulating film 142 may be disposed on the second gate electrode G2 of the second thin film transistor TFT2 and the third gate insulating film 133. The second interlayer insulating layer 142 may be formed of an inorganic film, for example, a silicon nitride layer, a silicon oxynitride layer, a silicon oxide layer, a titanium oxide layer, and/or an aluminium oxide layer.

A first data metal layer DTL1 may be disposed on the second interlayer insulating film 142. The first data metal layer DTL1 may include a first source connection electrode SBE3, a second source connection electrode SBE1, and a third source connection electrode SBE2. The first source connection electrode SBE3 may be connected to the first drain area D1 of the first active layer ACT1 through a first source contact hole PCT1 penetrating a first gate insulating film 131, a second gate insulating film 132, a first interlayer insulating film 141, a third gate insulating film 133, and a second interlayer insulating film 142. A second source connection electrode SBE1 may be connected to the second source area S2 of the second active layer ACT2 through the second source connection contact hole BCT1 penetrating the second interlayer insulating film 142 and the third gate insulating film 133. The third source connection electrode SBE2 may be connected to the second drain area D2 of the second active layer ACT2 through the third source connection contact hole BCT2 penetrating the second interlayer insulating film 142 and the third gate insulating film 133. The first data metal layer DTL1 may be formed as a single layer or multiple layers of one of molybdenum (Mo), aluminium (Al), chromium (Cr), gold (Au), titanium (Ti), nickel (Ni), neodymium (Nd), and/or copper (Cu), and/or an alloy thereof. For example, the first data metal layer DTL1 may include a first layer made of titanium (Ti), a second layer made of aluminum (Al), and a third layer made of titanium (Ti).

A first organic layer 160 may be disposed to flatten the step due to the first thin film transistor TFT1 and the second thin film transistor TFT2 on the first source connection electrode SBE3, the second source connection electrode SBE1, and the third source connection electrode SBE2, and the second interlayer insulating film 142. The first organic layer 160 may be formed from an organic film such as acrylic resin, epoxy resin, phenolic resin, polyamide resin, polyimide resin, and/or the like.

A second data metal layer DTL2 may be disposed on the first organic layer 160. The second data metal layer DTL2 may include a fourth source connection electrode SBE4. The fourth source connection electrode SBE4 may be connected to the first source connection electrode SBE3 through a second pixel contact hole PCT2 penetrating the first organic layer 160. The second data metal layer DTL2 may be formed as a single layer or multiple layers of one of molybdenum (Mo), aluminium (Al), chromium (Cr), gold (Au), titanium (Ti), nickel (Ni), neodymium (Nd), and/or copper (Cu), and/or an alloy thereof. For example, the second data metal layer DTL2 may include a first layer made of titanium (Ti), a second layer made of aluminum (Al), and/or a third layer made of titanium (Ti).

A second organic layer 180 may be disposed on the fourth source connection electrode SBE4 and the first organic layer 160. The second organic layer 180 may be formed of an organic layer such as acrylic resin, epoxy resin, phenolic resin, polyamide resin, polyimide resin, and/or the like.

The light emitting element layer EML may be disposed on the second organic layer 180. The light emitting element layer EML may include a common electrode CE, light emitting elements LE, pixel electrodes PXE1, PXE2, and PXE3, and an organic layer 190.

The common electrode CE may be disposed on the second organic layer 180. The common electrode CE may be a common layer commonly formed in the first sub-pixel SPX1, the second sub-pixel SPX2, and the third sub-pixel SPX3. The common electrode CE may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof. For example, the common electrode CE may be made of copper (Cu) with low sheet resistance to lower the resistance of the common electrode CE.

An organic pattern layer BOL may be disposed on the common electrode CE. The organic pattern layer BOL serves to temporarily fix or adhere the plurality of light emitting elements LE to prevent the plurality of light emitting elements LE from tilting or falling over in the process of transferring the plurality of light emitting elements LE to the display panel 100. That is, the organic pattern layer BOL may be a membrane for temporarily adhering the plurality of light emitting elements LE to a common electrode CE of each of the first sub-pixel SPX1, the second sub-pixel SPX2, and the third sub-pixel SPX3. To facilitate temporary adhesion, the thickness of the organic pattern layer BOL may be greater than the thickness of the common electrode CE and greater than the thickness of the contact electrode CTE (e.g., CTE1, CTE2).

The organic pattern layer BOL may be a photosensitive organic layer such as photoresist. Alternatively, the organic pattern layer BOL may be formed of acryl resin, epoxy resin, phenolic resin, polyamide resin, polyimide resin, and/or the like.

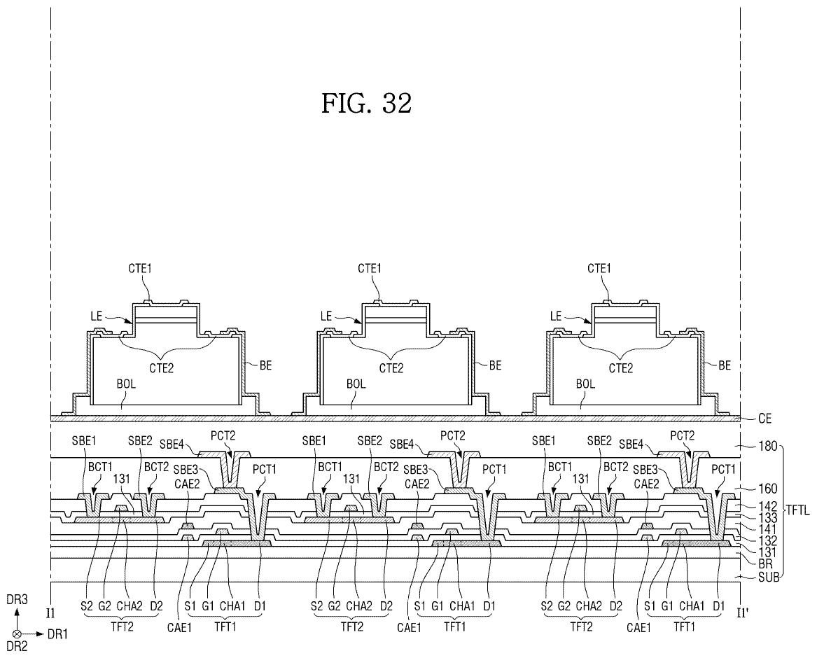

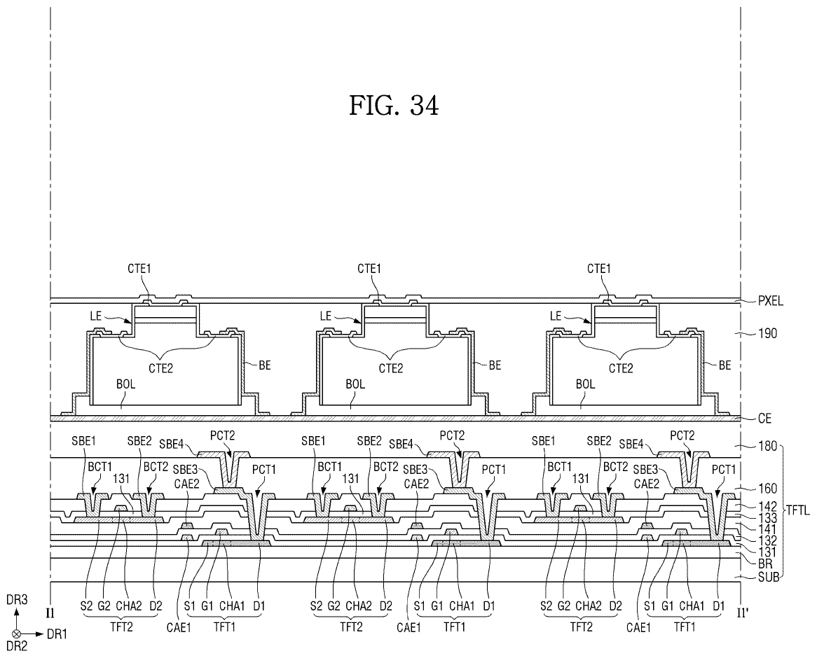

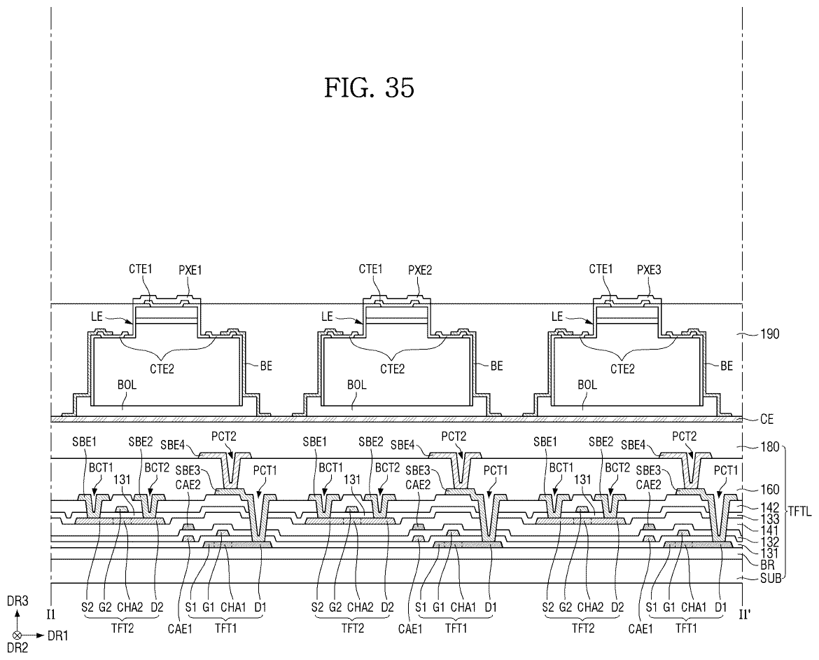

A detailed description of the organic pattern layer BOL will be described later in conjunction with FIGS. 32-42.

A plurality of light emitting elements LE may be disposed on the organic pattern layer BOL.

The plurality of light emitting elements LE may be directly transferred from the semiconductor substrate to the common electrode CE of the display panel 100.

Alternatively, the plurality of light emitting elements LE may be transferred to the display panel 100 through an electrostatic method using an electrostatic head or a stamp method using an elastic polymer material such as PDMS and/or silicon as a transfer substrate.

The third semiconductor layer SEM3 of the light emitting element LE may directly contact the organic pattern layer BOL. The light emitting element LE may completely overlap the organic pattern layer BOL. The organic pattern layer BOL may protrude outside the light emitting element LE but is not limited to this.

The light emitting element LE may be the light emitting element LE described with reference to FIGS. 6 and 7.

The pixel electrodes PXE1, PXE2, and PXE3 may be disposed on the first contact electrode CTE1 of the light emitting element LE. For example, the first pixel electrode PXE1 may be disposed on the first contact electrode CTE1 of the light emitting element LE of the first sub-pixel SPX1. The second pixel electrode PXE2 may be disposed on the first contact electrode CTE1 of the light emitting element LE of the second sub-pixel SPX2. The third pixel electrode PXE3 may be disposed on the first contact electrode CTE1 of the light emitting element LE of the third sub-pixel SPX3. The first contact electrode CTE1 of the light emitting element LE may overlap the pixel electrodes PXE1, PXE1, and PXE3.

The pixel electrodes PXE1, PXE1, and PXE3 may be made of a transparent conductive material (TCO) such as indium tin oxide (ITO) and/or indium zinc oxide (IZO) that may transmit light.

The connection electrode BE serves to connect the second contact electrode CTE2 and the common electrode CE of the light emitting element LE. To this end, the connection electrode BE may be connected to the second contact electrode CTE2 and the common electrode CE. The connection electrode BE may overlap at least a portion of the second contact electrode CTE2. The connection electrode BE may overlap at least a portion of the organic pattern layer BOL and at least a portion of the common electrode CE. The connection electrode BE may be around (e.g., may surround) at least a portion of the side surface of the light emitting element LE. For example, the connection electrode BE may be disposed on a portion of the protective layer INS0 of the light emitting element LE. The connection electrode BE may be around (e.g., may surround) the side of the second portion LEP2 of the light emitting element LE.

The connection electrode BE may include one of molybdenum (Mo), aluminum (Al), chromium (Cr), gold (Au), titanium (Ti), nickel (Ni), neodymium (Nd), and/or copper (Cu). Alternatively, the connection electrode BE may be made of a transparent conductive material (TCO) such as indium tin oxide (ITO) and/or indium zinc oxide (IZO) that may transmit light.

When the connection electrode BE is made of a highly reflective metal material such as aluminum (Al), light emitted from the active layer MQW of the light emitting element LE that proceeds in the side direction of the light emitting element LE may be reflected from the connection electrode BE and proceed in the upper direction of the light emitting element LE. Therefore, the light efficiency of the light emitting element LE may be increased because light loss from the light emitting element LE may be reduced.

In the first sub-pixel SPX1, the first pixel electrode PXE1 may be connected to the fourth source connection electrode SBE4 through the first connection hole (CT1 in FIG. 8) penetrating the second organic layer 180. In the second sub-pixel SPX2, the second pixel electrode PXE2 may be connected to the fourth source connection electrode SBE4 through the second connection hole (CT2 in FIG. 8) penetrating the second organic layer 180. In the third sub-pixel SPX3, the third pixel electrode PXE3 may be connected to the fourth source connection electrode SBE4 through the third connection hole (CT3 in FIG. 8) penetrating the second organic layer 180.

In the first sub-pixel SPX1, the first pixel electrode PXE1 may be connected to the first source area S1 or the first drain area D1 of the first thin film transistor TFT1 through the first source connection electrode SBE3 and the fourth source connection electrode SBE4. Therefore, the voltage controlled by the first thin film transistor TFT1 in the first sub-pixel SPX1 may be applied to the first pixel electrode PXE1.

In addition, in the second sub-pixel SPX2, the second pixel electrode PXE2 may be connected to the first source area S1 or the first drain area D1 of the first thin film transistor TFT1 through the first source connection electrode SBE3 and the fourth source connection electrode SBE4. Therefore, the voltage controlled by the first thin film transistor TFT1 in the second sub-pixel SPX2 may be applied to the second pixel electrode PXE2.

Further, in the third sub-pixel SPX3, the third pixel electrode PXE3 may be connected to the first source area S1 or the first drain area D1 of the first thin film transistor TFT1 through the first source connection electrode SBE3 and the fourth source connection electrode SBE4. Therefore, the voltage controlled by the first thin film transistor TFT1 in the third sub-pixel SPX3 may be applied to the third pixel electrode PXE3.

The third organic layer 190 may be disposed to cover a portion of the side surfaces of the connection electrode BE, the common electrode CE, and the plurality of light emitting elements LE. For example, the third organic layer 190 may be disposed to cover the connection electrode BE. Further, the third organic layer 190 may be disposed to cover the top surface of the second portion LEP2 and the side surface of the first portion LEP1 that are not covered by the connection electrode BE. The third organic layer 190 may be formed of an organic layer such as acryl resin, epoxy resin, phenolic resin, polyamide resin, polyimide resin, and/or the like.

The third organic layer 190 is a layer for flattening the steps caused by the plurality of light emitting elements LE. The third organic layer 190 may be disposed to expose the first contact electrode CTE1 of each of the plurality of light emitting elements LE.

The pixel electrodes PXE1, PXE2, and PXE3 may be referred to as an anode electrode or a first electrode, and the common electrode CE may be referred to as a cathode electrode or a second electrode.

The first capping layer CAP1 may be disposed on the pixel electrodes PXE1, PXE2, and PXE3, and the third organic layer 190. The first capping layer CAP1 may be formed of an inorganic film, for example, a silicon nitride layer, a silicon oxy nitride layer, a silicon oxide layer, a titanium oxide layer, and/or an aluminum oxide layer.

A light blocking layer BM, a first light conversion layer QDL1, a second light conversion layer QDL2, and a light transmitting layer TPL may be disposed on the first capping layer CAP1. The first light conversion layer QDL1, the second light conversion layer QDL2, and the light transmitting layer TPL may be formed by partitioning the light blocking layer BM. Therefore, the first light conversion layer QDL1 may be disposed on the first capping layer CAP1 in the first sub-pixel SPX1, and the second light conversion layer QDL1 may be disposed on the first capping layer CAP1 in the second sub-pixel SPX2, and the light transmitting layer TPL may be disposed on the first capping layer CAP1 in the third sub-pixel SPX3. The light blocking layer BM may overlap the bank 190 in the third direction DR3 and may not overlap the plurality of light emitting elements LE.

The first light conversion layer QDL1 may convert a portion of the third light (e.g., light in the blue wavelength band) incident from the light emitting element LE into first light (e.g., light in the red wavelength band). The first light conversion layer QDL1 may include a first base resin BRS1 and first wavelength conversion particles WCP1. The first base resin BRS1 may include a light-transmitting organic material. For example, the first base resin BRS1 may include an epoxy-based resin, an acrylic-based resin, a cardo-based resin, and/or an imide-based resin. The first wavelength conversion particle WCP1 may convert a portion of the third light (light in the blue wavelength band) incident from the light emitting element LE into first light (e.g., light in the red wavelength band). The first wavelength conversion particle WCP1 may be a quantum dot (QD), a quantum rod, a fluorescent material, and/or a phosphorescent material.

The second light conversion layer QDL2 may convert a portion of the third light (e.g., light in the blue wavelength band) incident from the light emitting element LE into second light (e.g., light in the green wavelength band). It may include the second base resin BRS2 and the second wavelength conversion particle WCP2. The second base resin BRS2 may include a light transmitting organic material. For example, the second base resin BRS2 may include epoxy resin, acrylic resin, cardo resin, and/or imide resin. The second wavelength conversion particle WCP2 may convert a portion of the third light (e.g., light in the blue wavelength band) incident from the light emitting element LE into second light (e.g., light in the green wavelength band). The second wavelength conversion particle WCP2 may be a quantum dot (QD), a quantum rod, a fluorescent material, and/or a phosphorescent material.

The light transmitting layer TPL may include a light transmitting organic material. For example, the light transmitting layer TPL may include epoxy resin, acrylic resin, cardo resin, and/or imide resin.

The light blocking layer BM may include a first light blocking layer BM1 and a second light blocking layer BM2 that are sequentially stacked in the third direction DR3. A length in a first direction DR1 or a length in a second direction DR2 of the first light blocking layer BM1 may be greater than a length in a first direction DR1 or a length in a second direction DR2 of the second light blocking layer BM2. The first light blocking layer BM1 and the second light blocking layer BM2 may be formed from an organic layer such as acrylic resin, epoxy resin, phenolic resin, polyamide resin, polyimide resin, and/or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as carbon black and/or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and the side and top surfaces of the second light blocking layer BM2.

The reflective layer RF may be disposed between the light blocking layer BM and the first light conversion layer QDL1, between the light blocking layer BM and the second light conversion layer QDL2, and between the light blocking layer BM and the light transmitting layer TPL. The reflective layer RFL serves to reflect light proceeding in the lateral direction from the first light conversion layer QDL1, the second light conversion layer QDL2, and the light transmitting layer TPL.

The reflective layer RF may include a highly reflective metal material such as aluminum (Al). The thickness of the reflective layer RF may be approximately 0.1 μm.

Alternatively, the reflective layer RF may include M (M is an integer of 2 or more) pairs of first and second layers having different refractive indices to serve as Distributed Bragg Reflectors (DBR). In this case, M first layers and M second layers may be arranged alternately. The first layer and the second layer may be formed of an inorganic film, for example, a silicon nitride layer, a silicon oxy nitride layer, a silicon oxide layer, a titanium oxide layer, or an aluminum oxide layer.

The third capping layer CAP3 may be disposed on the second capping layer CAP2, the first light conversion layer QDL1, the second light conversion layer QDL2, and the light transmitting layer TPL. The third capping layer CAP3 may be formed of an inorganic film, for example, a silicon nitride layer, a silicon oxy nitride layer, a silicon oxide layer, a titanium oxide layer, and/or an aluminum oxide layer. The first light conversion layer QDL1, the second light conversion layer QDL2, and the light transmitting layer TPL may be encapsulated by the first capping layer CAP1, the second capping layer CAP2, and the third capping layer CAP3.

The fifth organic layer 193 may be disposed on the third capping layer CAP3. The fifth organic layer 193 may be formed of acryl resin, epoxy resin, phenolic resin, polyamide resin, polyimide resin, and/or the like.

A plurality of color filters CF1, CF2, and CF3 may be disposed on the fifth organic layer 193. The plurality of color filters CF1, CF2, and CF3 may include first color filters CF1, second color filters CF2, and third color filters CF3.

The first color filter CF1 disposed in the first sub-pixel SPX1 may transmit the first light (e.g., light in the red wavelength band) and absorb and/or block third light (e.g., light in the blue wavelength band). Therefore, the first color filter CF1 may transmit the first light (e.g., light in the red wavelength band) converted by the first light conversion layer QDL1 from among the third light (e.g., light in the blue wavelength band) emitted by the light emitting element LE and absorb and/or block the third light (e.g., light in the blue wavelength band) not converted by the first light conversion layer QDL1. Accordingly, the first sub-pixel SPX1 may emit first light (e.g., light in a red wavelength band).

The second color filter CF2 disposed in the second sub-pixel SPX2 may transmit the second light (e.g., light in the green wavelength band) and absorb and/or block the third light (e.g., light in the blue wavelength band). Therefore, the second color filter CF2 may transmit the second light (e.g., light in the green wavelength band) converted by the second light conversion layer QDL2 from among the third light (e.g., light in the blue wavelength band) emitted by the light emitting element LE and absorb and/or block the third light (e.g., light in the blue wavelength band) not converted by the second light conversion layer QDL2. Accordingly, the second sub-pixel SPX2 may emit second light (e.g., light in the green wavelength band).

The third color filter CF3 disposed in the third sub-pixel SPX3 may transmit the third light (e.g., light in the blue wavelength band). Therefore, the third color filter CF3 may transmit the third light (e.g., light in the blue wavelength band) emitted from the light emitting element LE through the light transmitting layer TPL. Accordingly, the third sub-pixel SPX3 may emit the third light (e.g., light in the blue wavelength band).

The first color filter CF1, the second color filter CF2, and the third color filter CF3 overlapping in the third direction DR3 may overlap with the third organic layer 190 and the light blocking layer BM in the third direction DR3.

A sixth organic layer 194 for planarization may be disposed on the plurality of color filters CF1, CF2, and CF3. The sixth organic layer 194 may be formed of acryl resin, epoxy resin, phenolic resin, polyamide resin, polyimide resin, and/or the like.

According to FIGS. 9 and 10, the light emitting element LE may include a first portion LEP1 and a second portion LEP2 of a multi-stage structure and may include a first contact electrode CTE1 disposed on the first portion LEP1 and a second contact electrode CTE2 disposed on the second portion LEP2. The first pixel electrode PXE1, the second pixel electrode PXE2, and the third pixel electrode PXE3 may be disposed on a top surface of the light emitting element LE, and the common electrode CE may be disposed on a bottom surface of the light emitting element LE. The pixel electrodes PXE1, PXE2, and PXE3 are disposed on the first contact electrode CTE1, and the second contact electrode CTE2 is connected to the common electrode CE through the connection electrode BE.

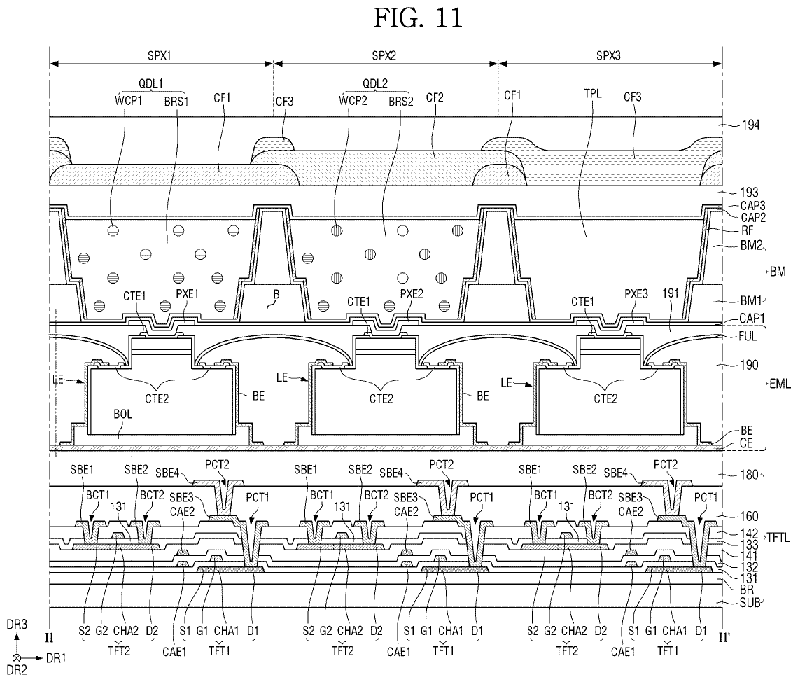

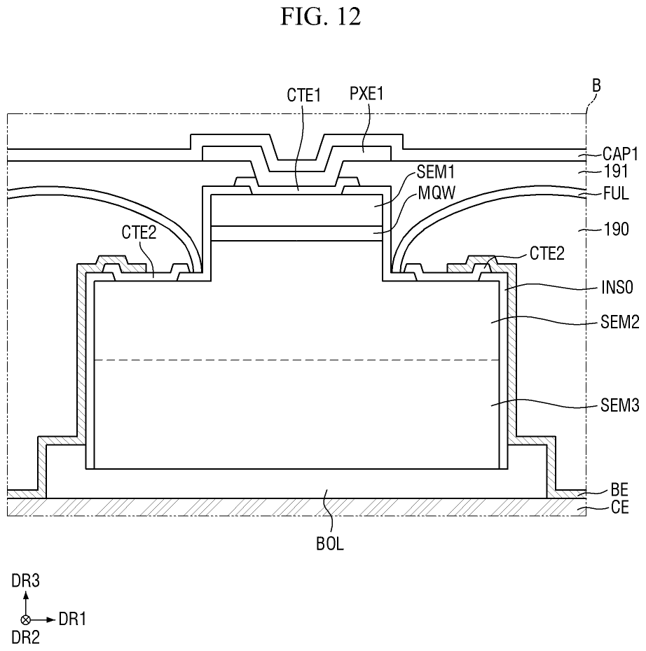

FIG. 11 is a cross-sectional view illustrating another example of a cross-section of the display panel corresponding to the line 11-11′ of FIG. 8. FIG. 12 is a cross-sectional view illustrating one example of an area B of FIG. 11 in detail.

The embodiments of FIGS. 11 and 12 differ from the embodiments of FIGS. 9 and 10 in that the organic layer covering the light emitting element LE is formed of multiple layers, and a functional layer FUL is added between the stacked organic layers 190 and 191. The embodiments of FIGS. 11 and 12 omit descriptions that are redundant with the embodiments of FIGS. 8 and 10.

Referring to FIGS. 11 and 12, a light emitting element layer EML further includes a stacked multi-layer organic layer 190 and 191 and a functional layer FUN disposed between the stacked organic layers 190 and 191.

The third organic layer 190 and a fourth organic layer 191 may be disposed to flatten the light emitting element LE.

The third organic layer 190 may be disposed to cover at least a portion of the side surface of the light emitting element LE including the second contact electrode CTE2. The third organic layer 190 may be disposed higher from the center to the side of the sub-pixels SPX1, SPX2, and SPX3.

The fourth organic layer 191 may be disposed on the third organic layer 190. The fourth organic layer 191 may be disposed no higher than the light emitting element LE. For example, the first contact electrode CTE1 of the light emitting element LE may be exposed by the fourth organic layer 191.

The fourth organic layer 191 may be formed of an organic layer such as acryl resin, epoxy resin, phenolic resin, polyamide resin, polyimide resin, and/or the like.

The functional layer FUN may be disposed between the third organic layer 190 and the fourth organic layer 191.

The functional layer FUN may be a reflective layer containing a highly reflective metal material such as reflective aluminum (Al). When the functional layer FUN includes a metal material with high reflectivity, the light emission efficiency of the light emitting element LE may be improved.

The functional layer FUN may be a protective layer formed of an inorganic film, for example, a silicon nitride layer, a silicon oxy nitride layer, a silicon oxide layer, a titanium oxide layer, and/or an aluminum oxide layer. When the functional layer FUN includes an inorganic film, the reliability of the light emitting element LE may be improved.

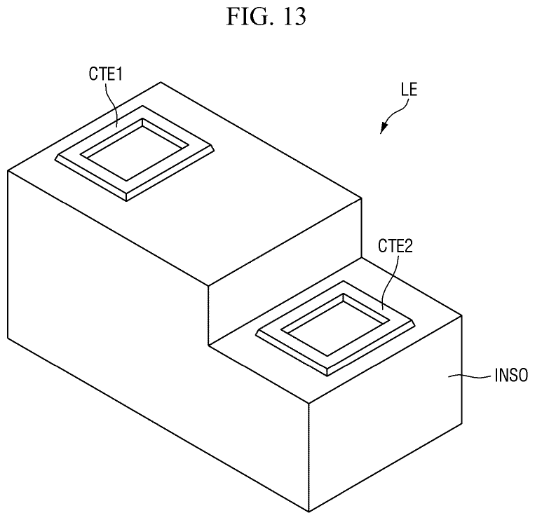

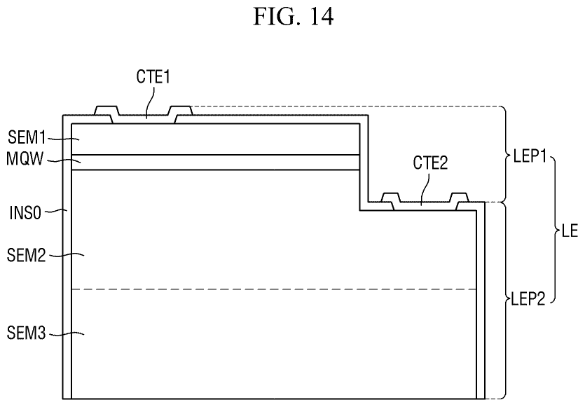

FIG. 13 is a perspective view illustrating the structure of a light emitting element according to one or more embodiments. FIG. 14 is a cross-sectional view illustrating the structure of a light emitting element according to one or more embodiments.

The embodiments of FIGS. 13 and 14 differ from the embodiments of FIGS. 6 and 7 in that the first portion LEP is arranged to be aligned with one side of the second portion LEP2 in a straight line. Descriptions of the embodiments of FIGS. 13 and 14 may omit descriptions that may be redundant with the embodiments of FIGS. 6 and 7.

Referring to FIGS. 13 and 14, it may be a vertical type micro LED extending in the third direction DR3. The vertical micro LED refers to an LED having a structure in which a third semiconductor layer SEM3, a second semiconductor layer SEM2, an active layer MQW, and a first semiconductor layer SEM1 are sequentially arranged along a third direction DR3 that is a vertical direction.

The light emitting element LE includes a first portion LEP1 and a second portion LEP2. The first portion LEP1 may be disposed on the second portion LEP2. The first portion LEP1 is arranged to be aligned in a straight line with one side of the second portion LEP2.

The first portion LEP1 includes a first contact electrode CTE1, a first semiconductor layer SEM1, an active layer MQW, a second semiconductor layer SEM2, and a protective layer INS0. The second portion LEP2 includes a second contact electrode CTE2, a second semiconductor layer SEM2, a third semiconductor layer SEM3, and the protective layer INS0. The second semiconductor layer SEM2 of the first portion LEP1 may be connected to the second semiconductor layer SEM2 of the second portion LEP2. The diameter of the first portion LEP1 may be less than the diameter of the second portion LEP2. The second portion LEP2 that does not overlap the first portion LEP1 may be exposed to the outside.

The first contact electrode CTE1 may be disposed on the first semiconductor layer SEM1 of the first portion LEP1. The first contact electrode CTE1 may be disposed on the top surface of the first semiconductor layer SEM1.

The second contact electrode CTE2 may be disposed on the top surface of the second semiconductor layer SEM2 of the second portion LEP2 that does not overlap the first portion LEP1.

The protective layer INS0 may be disposed on the top surface of the first portion LEP1 and the second portion LEP2 where the first contact electrode CTE1 and the second contact electrode CTE2 are not disposed, and on the sides of the first portion LEP1 and the second portion LEP2. The protective layer INS0 may be formed of an inorganic film, for example, a silicon nitride layer, a silicon oxynitride layer, a silicon oxide layer, a titanium oxide layer, and/or an aluminum oxide layer.

The common electrode CE may be a common layer commonly formed in the first sub-pixel SPX1, the second sub-pixel SPX2, and the third sub-pixel SPX3 arranged along the first direction DR1.

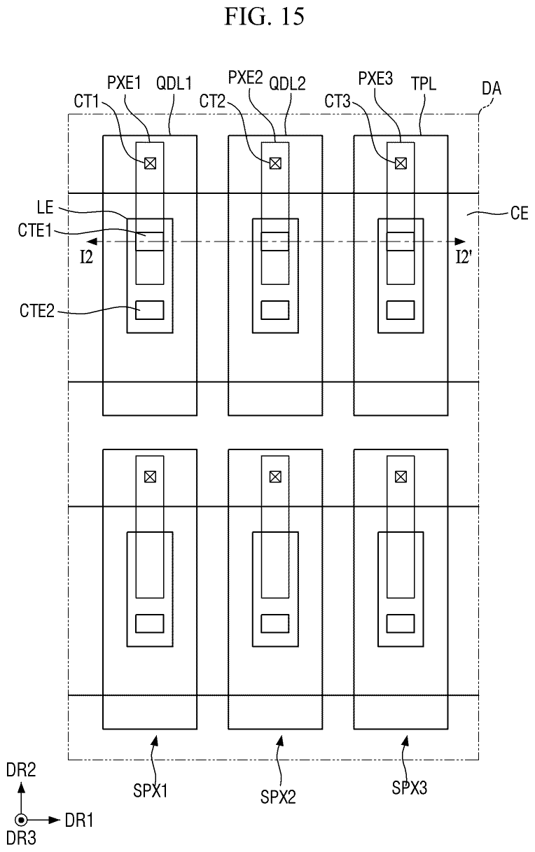

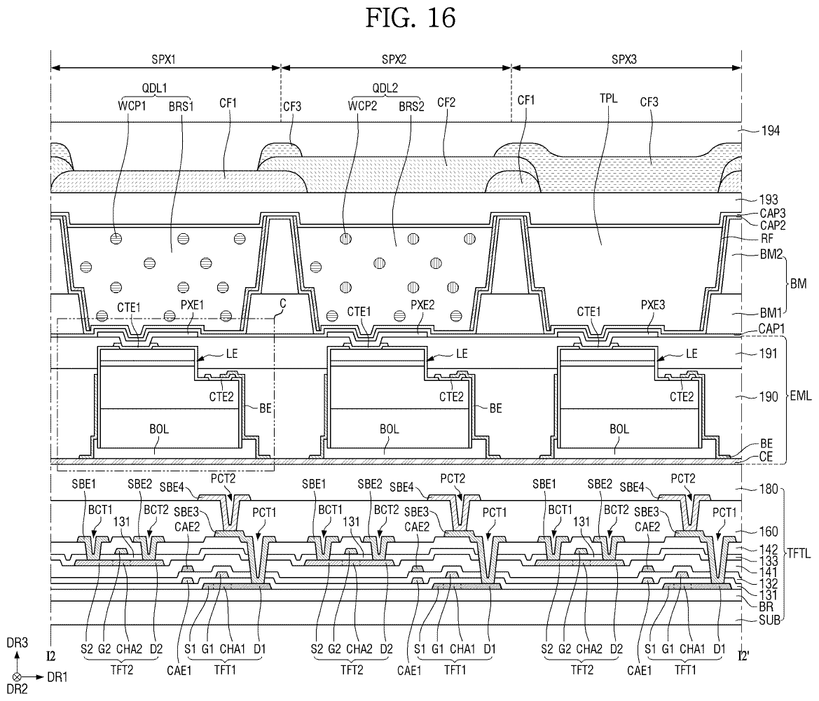

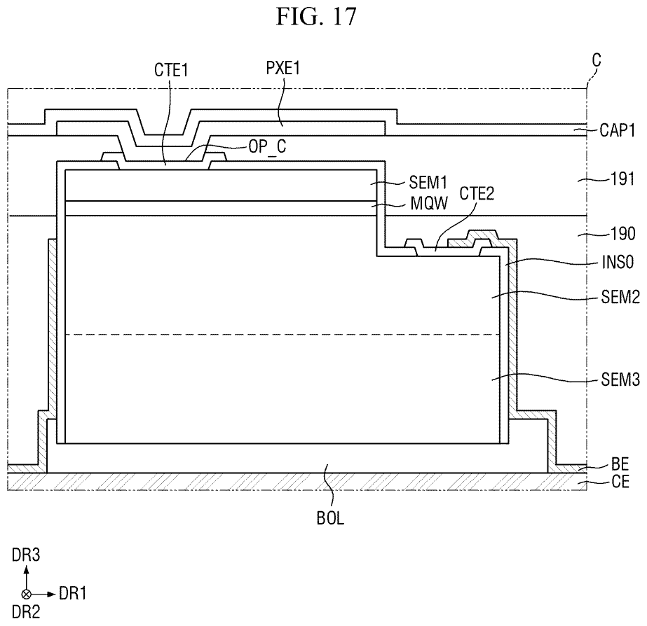

FIG. 15 is a layout diagram illustrating pixels of a display area according to one or more embodiments. FIG. 16 is a cross-sectional view illustrating one example of a cross-section of a display panel corresponding to the line 12-12′ of FIG. 15. FIG. 17 is a cross-sectional view illustrating one example of an area C of FIG. 16 in detail.

Referring to FIGS. 15 to 17, the embodiments of FIGS. 16 and 17 differ from the embodiments of FIGS. 11 and 12 in that they include the light emitting elements LE described with reference to FIGS. 13 and 14, and in that they include stacked multilayered organic layers 190, 191, and in the embodiment of FIGS. 11 and 12, descriptions overlapping with the embodiment of FIGS. 8-10 will be omitted.

The connection electrode BE serves to connect the second contact electrode CTE2 of the light emitting element LE and the common electrode CE. To this end, the connection electrode BE may be connected to the second contact electrode CTE2 and the common electrode CE. The connection electrode BE may overlap at least a portion of the second contact electrode CTE2. The connection electrode BE may overlap at least a portion of the organic pattern layer BOL and at least a portion of the common electrode CE. The connection electrode BE may be around (e.g., may surround) at least a portion of the side surface of the light emitting element LE. For example, the connection electrode BE may be disposed on a portion of the protective layer INS0 of the light emitting element LE. The connection electrode BE may be around (e.g., may surround) the side of the second portion LEP2 of the light emitting element LE. The connection electrode BE may be disposed lower than the active layer MQW.

The third organic layer 190 may be around (e.g., may surround) the second portion LEP2. The third organic layer 190 may cover the connection electrode BE. The fourth organic layer 191 may be around (e.g., may surround) the first portion LEP1. The fourth organic layer 191 may be formed to completely cover the light emitting element LE. When the fourth organic layer 191 is formed to completely cover the light emitting element LE, it may include an opening OP_C exposing the first contact electrode CTE1.

The pixel electrodes PXE1, PXE1, and PXE3 may be disposed on the first contact electrode CTE1 of the light emitting element LE. For example, the first pixel electrode PXE1 may be disposed on the first contact electrode CTE1 of the light emitting element LE of the first sub-pixel SPX1. The second pixel electrode PXE2 may be disposed on the first contact electrode CTE1 of the light emitting element LE of the second sub-pixel SPX2. The third pixel electrode PXE3 may be disposed on the first contact electrode CTE1 of the light emitting element LE of the third sub-pixel SPX3. The first contact electrode CTE1 of the light emitting element LE may overlap the pixel electrodes PXE1, PXE1, and PXE3.

The width of the organic pattern layer BOL may be equal to or greater than the width of the light emitting element LE.

Each of the plurality of pixels PX in the display area DA may include a first sub-pixel SPX1, a second sub-pixel SPX2, and a third sub-pixel SPX3.

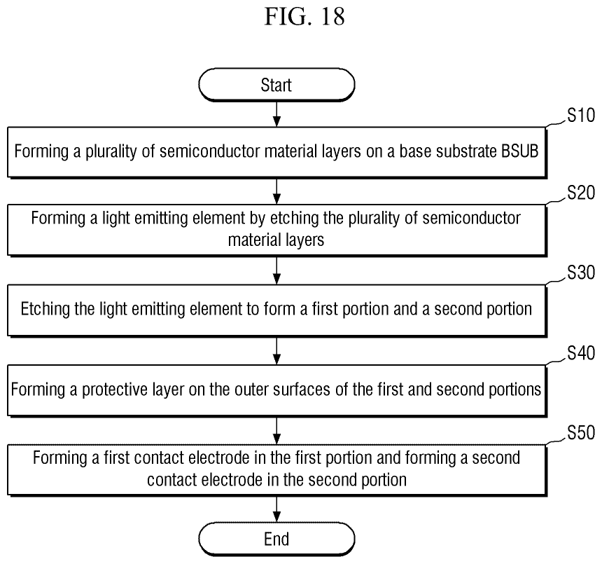

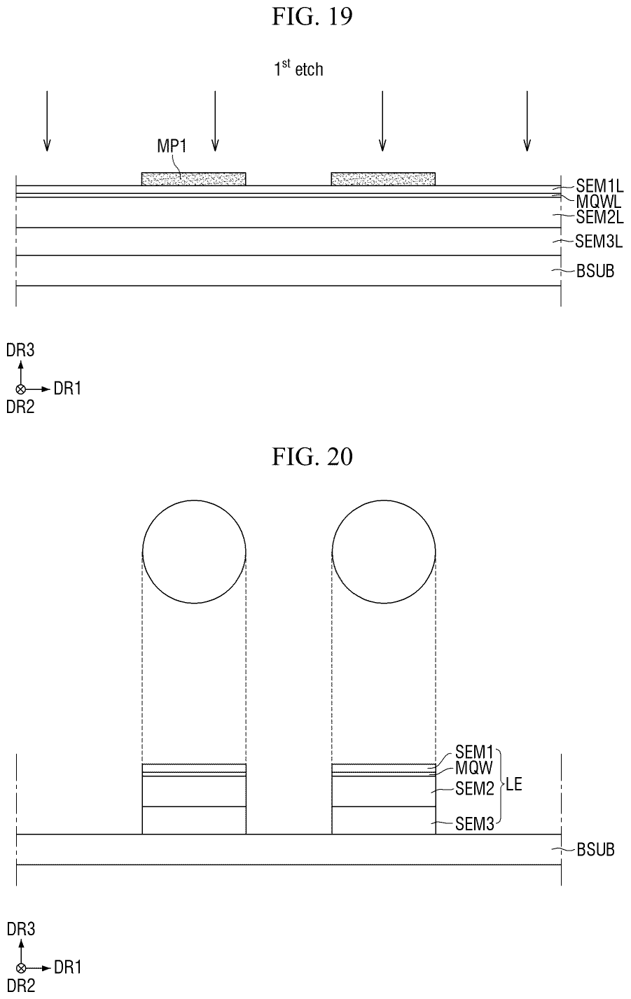

FIG. 18 is a flowchart illustrating a method of manufacturing a light emitting element according to one or more embodiments. FIGS. 19-24 are cross-sectional views to illustrate a method of manufacturing a light emitting element according to one or more embodiments. FIGS. 19-24 show one example of cross-sectional and a plan view of a light emitting elements on a growth substrate corresponding to the light emitting element with reference to FIG. 6.

Referring to FIG. 19, a base substrate BSUB is prepared. The base substrate BSUB may be a sapphire substrate (Al₂O₃) or a silicon wafer containing silicon. However, it is not limited thereto, and one or more embodiments will be described by way of example when the base substrate BSUB is a sapphire substrate.

A plurality of semiconductor material layers SEM3L, SEM2L, MQWL, and SEM1L are formed on the base substrate BSUB. (S10 in FIG. 18) A plurality of semiconductor material layers grown by the epitaxial method may be formed by growing a seed crystal. Here, the method of forming the semiconductor material layer may be electron beam deposition, physical vapor deposition (PVD), chemical vapor deposition (CVD), plasma laser deposition (PLD), dual-type thermal evaporation, sputtering, metal organic chemical vapor deposition (MOCVD), and the like, and preferably formed by metal organic chemical vapor deposition (MOCVD). However, it is not limited thereto.

The precursor material for forming the plurality of semiconductor material layers is not particularly limited within a range that may be conventionally selected to form the target material. In one example, the precursor material may be a metal precursor containing an alkyl group such as a methyl group or an ethyl group. For example, it may be a compound such as trimethyl gallium (Ga(CH₃)₃), trimethyl aluminum (Al(CH₃)₃), and/or triethyl phosphate ((C₂H₅)₃PO₄), but is not limited thereto.

Specifically, the third semiconductor material layer SEM3L is formed on the base substrate BSUB. The drawings illustrate that the third semiconductor material layer SEM3L is further stacked, but it is not limited thereto, and a plurality of layers may be formed. The third semiconductor material layer SEM3L may be disposed to reduce a lattice constant difference between a second semiconductor material layer SEM2L and the base substrate BSUB. In one example, the third semiconductor material layer SEM3L may include an undoped semiconductor, which may be an n-type or p-type undoped material. In one or more embodiments, the third semiconductor material layer SEM3L may be at least one of undoped InAlGaN, GaN, AlGaN, InGaN, AlN, and InN, but is not limited thereto.

The second semiconductor material layer SEM2L, an active material layer MQWL, and a first semiconductor material layer SEM1L are sequentially formed on the third semiconductor material layer SEM3L using the above-described method.

Next, the plurality of semiconductor material layers SEM3L, SEM2L, MQWL, and SEM1L are etched to form the light emitting element LE (S20 in FIG. 18), and the light emitting element is etched to form the first portion LEP1 and the second portion LEP2 of the light emitting element LE. (S30 in FIG. 18)

For example, a plurality of first mask patterns MP1 are formed on the first semiconductor material layer SEM1L. The first mask pattern MP1 may be a hard mask containing an inorganic material or a photoresist mask containing an organic material. The first mask pattern MP1 prevents the plurality of semiconductor material layers SEM3L, SEM2L, MQWL, and SEM1L that are disposed below the first mask pattern MP1 from being etched. Then, a portion of the plurality of semiconductor material layers SEM3L, SEM2L, MQWL, and SEM1L is first etched using the plurality of first mask patterns MP1 as a mask.

On the base substrate BSUB, the plurality of semiconductor material layers SEM3L, SEM2L, MQWL, and SEM1L non-overlapping with the first mask pattern MP1 are etched and removed, and the non-etched portion overlapping with the first mask pattern MP1 may be formed of the plurality of semiconductor material layers SEM3L, SEM2L, MQWL, and SEM1L.

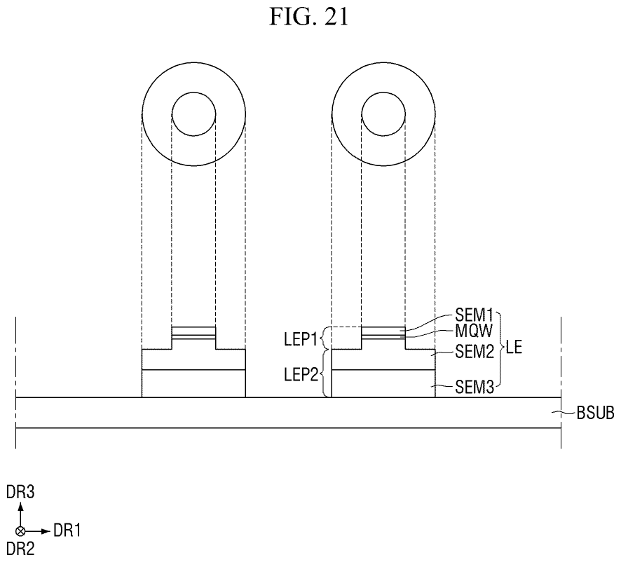

Referring to FIG. 21, a portion of the first etched semiconductor materials SEM3, SEM2, MQW, and SEM1 that have been first etched is second etched. The second etching forms a narrow first portion LEP1 and a relatively wide second portion LEP2. The process for secondary etching may be dry etching, wet etching, reactive ion etching (RIE), deep reactive ion etching (DRIE), inductively coupled plasma reactive ion etching (ICP-RIE), and/or the like.

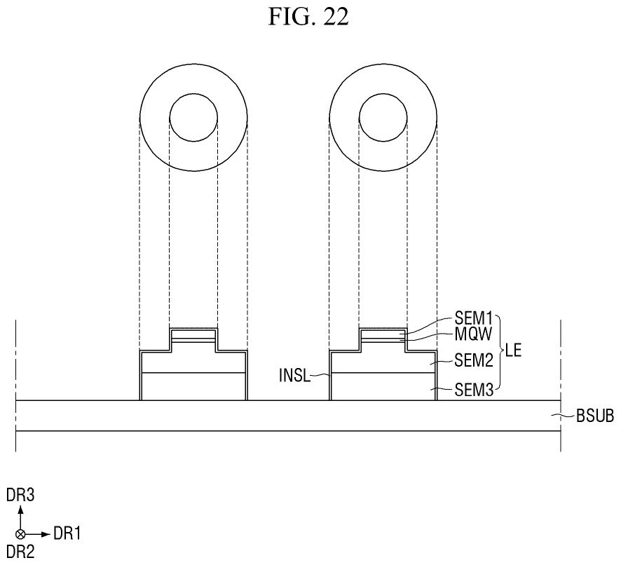

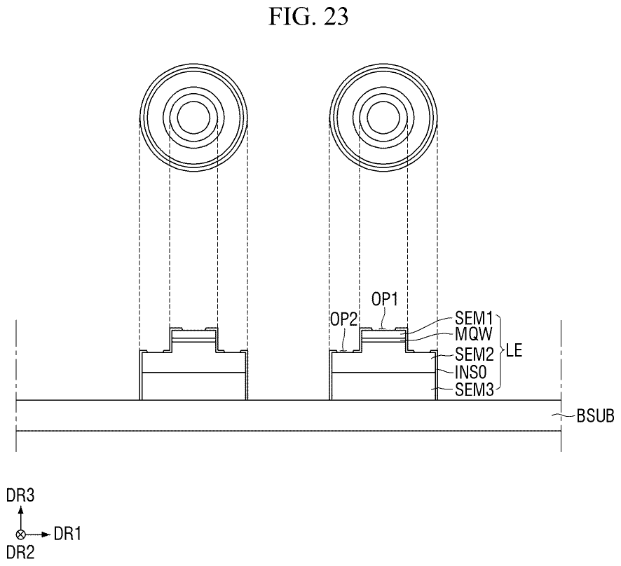

Referring to FIGS. 22 and 23, a protective layer INS0 is formed on the base substrate BSUB on which the light emitting element LE is formed. (S40 in FIG. 18)

For example, an insulating material layer INSL is formed on the outer surface of the plurality of light emitting elements LE. The insulating material layer INSL may be formed on the entire surface of the base substrate BSUB and may be formed not only on the light emitting element LE but also on the top surface of the base substrate BSUB exposed by the light emitting element LE.

Next, a third etch in which the insulating material layer INSL is partially removed is performed to form the protective layer INS0 of the light emitting element LE. (S40 in FIG. 18)

For example, an etching process may be performed in which a portion of the insulating material layer INSL is partially removed so that the insulating material layer INSL exposes the top surface of the light emitting element LE but is around (e.g., surrounds) the sides of the light emitting element LE. For example, in this process, the insulating material layer INSL may remove at least a portion of the top surface of the first semiconductor layer SEM1 of the light emitting element LE to define a first opening OP1. Further, the insulating material layer INSL may define a second opening OP2 by removing at least a portion of the second semiconductor layer SEM2 of the light emitting element LE. The process of partially removing the insulating material layer INSL may be performed by an etching process using a mask.

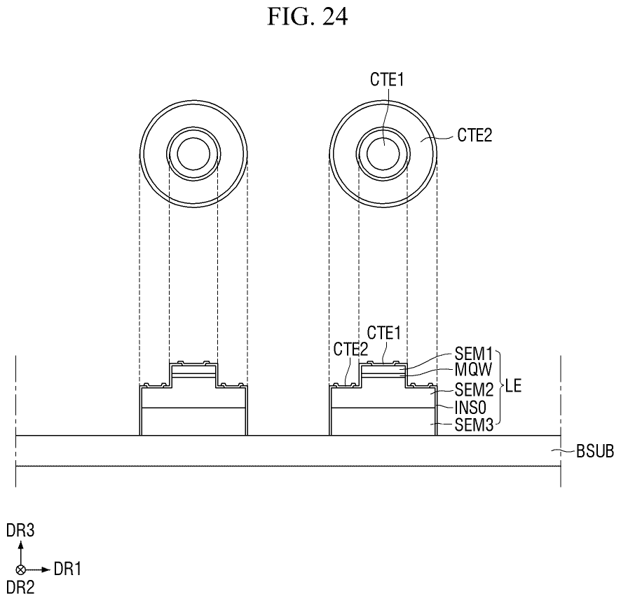

Next, referring to FIG. 24, a light emitting element LE may be formed by forming a first contact electrode CTE1 and a second contact electrode CTE2 on the light emitting element LE. (S50 in FIG. 18)

For example, the first contact electrode CTE1 and the second contact electrode CTE2 are formed by stacking a contact electrode material layer on the base substrate BSUB. Then, the contact electrode material layer is etched by an etching process to form the first contact electrode CTE1 covering the first opening OP1 and the second contact electrode CTE2 covering the second opening OP2 of the light emitting element LE. The contact electrode material layer may be formed of a transparent conductive material. For example, the contact electrode material layer may be a transparent conductive oxide such as indium tin oxide (ITO) and/or indium zinc oxide (IZO).

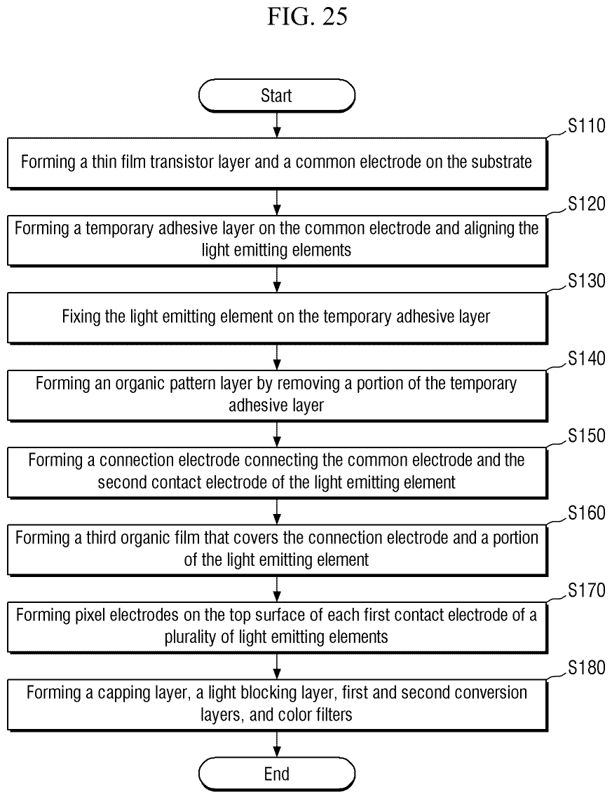

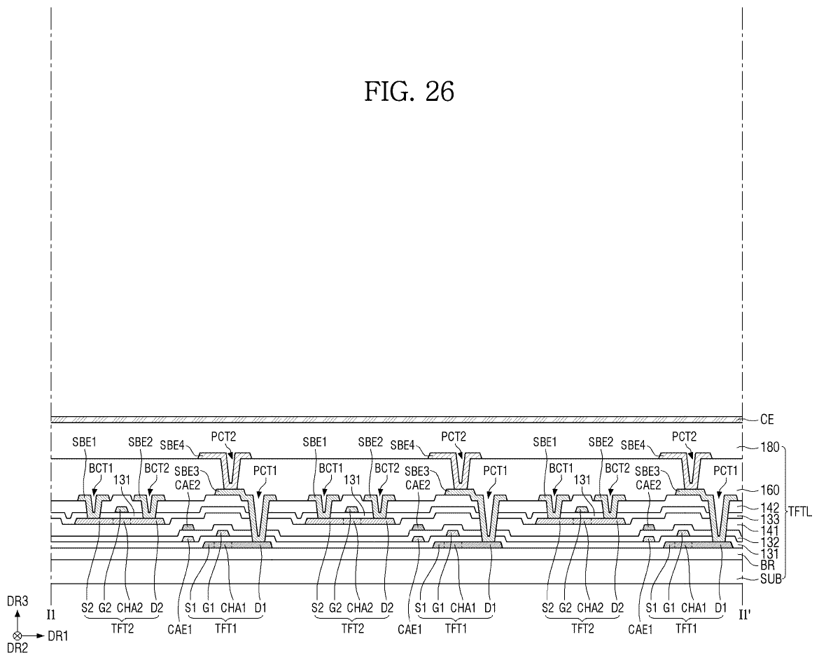

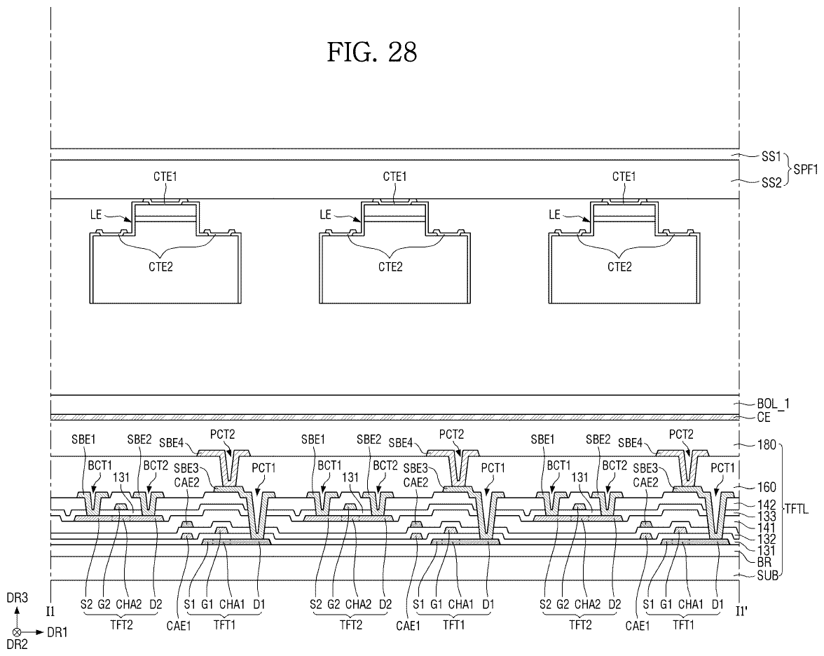

FIG. 25 is a flowchart illustrating a method of manufacturing a display device according to one or more embodiments. FIGS. 26-36 are cross-sectional views to illustrate a method of manufacturing a display device according to one or more embodiments. FIGS. 26-36 show examples of cross sections of the display panel corresponding to the line 11-11′ in FIG. 8.

First, a thin film transistor layer TFTL and a common electrode CE are formed on the substrate SUB as shown in FIG. 26. (S110 in FIG. 25)

A barrier film BR is formed on the substrate SUB, and the first channel areas CHA1, the first source areas S1, and the first drain areas D1 of the first thin film transistor TFT1 are formed on the barrier film BR using a photolithography process.

Then, a first gate insulating film 131 is formed on the first channel areas CHA1, the first source areas S1, and the first drain areas D1 of the first thin film transistor TFT1, and the first gate electrodes G1 and the first capacitor electrodes CAE1 of the first thin film transistor TFT1 are formed on the first gate insulating film 131. The first channel areas CHA1, first source areas S1, and first drain areas D1 of the first thin film transistors TFT1 may include polycrystalline silicon, monocrystalline silicon, low-temperature polycrystalline silicon, and/or amorphous silicon.

Then, a second gate insulating film 132 is formed on the first gate electrodes G1 and the first capacitor electrodes CAE1 of the first thin film transistors TFT1, and a second capacitor electrode CAE2 is formed on the second gate insulator film 132 using the photolithography process.

Then, a first interlayer insulating film 141 is formed on the second capacitor electrodes CAE, and the second channel areas CHA2, the second source areas S2, and the second drain areas D2 of the second thin-film transistor TFT2 are formed on the first interlayer insulating film 141 using the photolithography process. The second channel areas CHA2, the second source areas S2, and the second drain areas D2 of the second thin-film transistor TFT2 may include an oxide semiconductor including indium (In), gallium (Ga), and/or oxygen (O).

Then, a third gate insulating layer 133 is formed on the second channel areas CHA2, the second source areas S2, and the second drain areas D2 of the second thin-film transistor TFT2, second gate electrodes G2 of the second thin film transistors TFT2 are formed on the third gate insulating film 133 using the photolithography process.

Then, a second interlayer insulating film 142 is formed on the second gate electrodes G2 of the second thin film transistors TFT2. Further, the photolithography process is used to form a first source contact hole PCT1 penetrating the first gate insulating film 131, the second gate insulating film 132, the first interlayer insulating film 141, the third gate insulating film 133, and the second interlayer insulating film 142, the second source connection contact hole BCT1 penetrating the second interlayer insulating film 142 and the third gate insulating film 133, and the third source connection contact hole BCT2 penetrating the second interlayer insulating film 142 and the third gate insulating film 133. Additionally, the first source connection electrode SBE3, the second source connection electrode SBE1, and the third source connection electrode SBE2 are formed on the second interlayer insulating film 142 using the photolithography process.

Then, the first organic layer 160 is formed on the first source connection electrode SBE3, the second source connection electrode SBE1, and the third source connection electrode SBE2, and a fourth source connected electrode SBE4 is formed on the first organic layer 160 using the photolithography process.

Then, the second organic layer 180 is formed on the fourth source connection electrode SBE4, and the common electrode CE is formed on the second organic layer 180 using the photolithography process.

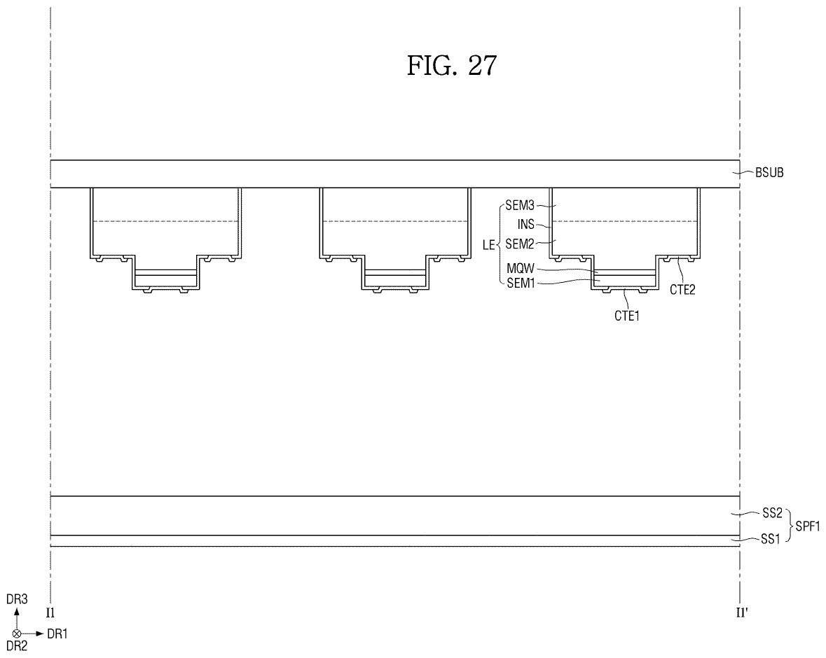

Second, as shown in FIGS. 26 and 27, a temporary adhesive layer BOL_1 (or temporary adhesive layer or temporary fixing layer) is formed on the common electrode CE, and the light emitting elements LE are aligned. (S120 in FIG. 25)

The temporary adhesive layer BOL_1 serves to temporarily fix or adhere the plurality of light emitting elements LE to prevent the plurality of light emitting elements LE from tipping over or falling down in the process of transferring the plurality of light emitting elements LE to the display panel 100. For this purpose, the thickness of the temporary adhesive layer BOL_1 may be approximately 2 μm or less, but the present disclosure is not limited thereto.

The temporary adhesive layer BOL_1 may be a photosensitive organic layer such as photoresist. Alternatively, the temporary adhesive layer BOL_1 may be formed of acryl resin, epoxy resin, phenolic resin, polyamide resin, polyimide resin, and/or the like.

A support film SPF1 is attached on the plurality of light emitting elements LE to transfer the plurality of light emitting elements LE grown on the base substrate BSUB to the display panel 100.

For example, the support film SPF1 is attached on the plurality of light emitting elements LE. The support film SPF1 may be aligned on the plurality of light emitting elements LE and attached to the first contact electrode CTE1 and in one or more embodiments to the second contact electrode CTE2 of the plurality of light emitting elements LE. The plurality of light emitting elements LE may be arranged in large numbers and may be attached to the support film SPF1 without being detached.

The support film SPF1 may be composed of a support layer SS2 and an adhesive layer SS1 disposed on the support layer SS2. The support layer SS2 may be made of a material that is transparent and mechanically stable to allow light to pass through. For example, the support layer SS2 may include a transparent polymer such as polyester, polyacrylic, polyepoxy, polyethylene, polystyrene, polyethylene terephthalate, and/or the like. The adhesive layer SS1 may include an adhesive material for bonding the light emitting element LE. For example, the adhesive material may include urethane acrylate, epoxy acrylate, polyester acrylate, and/or the like. The adhesive material may be a material whose adhesive strength changes as ultraviolet (UV) light or heat is applied, and thus the adhesive layer SS1 may be easily separated from the light emitting element LE.

Next, the base substrate BSUB is irradiated with a first laser to separate the light emitting element LE from the base substrate BSUB. The base substrate BSUB is separated from each third semiconductor layer SEM3 of the plurality of light emitting elements LE.

The process for separating the base substrate BSUB may be separated by a laser lift off (LLO) process. The laser lift off process utilizes a laser, and a KrF excimer laser (248 nm wavelength) may be used as the source. The energy density of the excimer laser is irradiated in the range of about 550 550 mJ/cm to 950 550 mJ/cm², and the incident area may be in the range of 50×50 μm² to 1×1 cm² but is not limited thereto. The base substrate BSUB may be separated from the light emitting element LE by irradiating the base substrate BSUB with the laser.

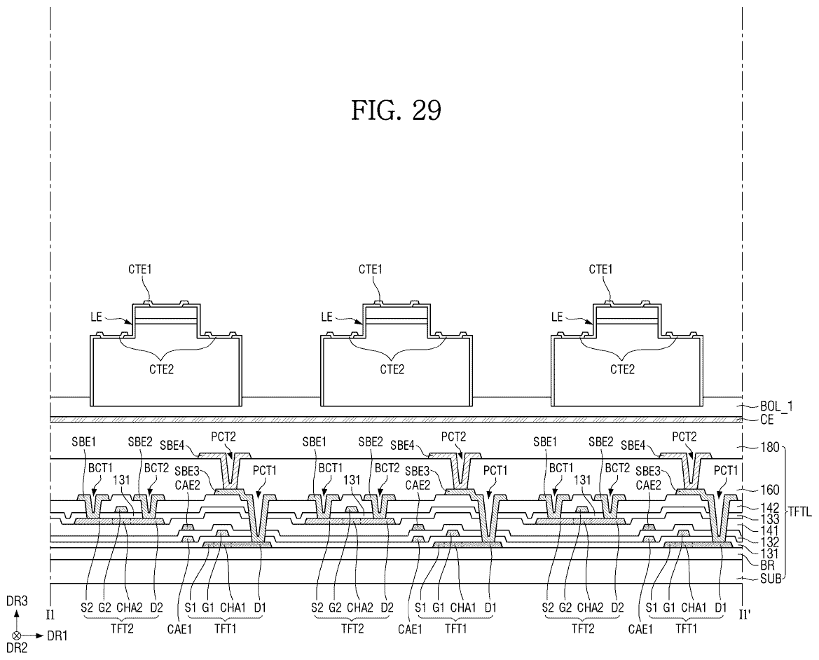

Third, as shown in FIG. 29, a plurality of light emitting elements LE are fixed to the temporary adhesive layer BOL_1, and the base substrate BSUB is detached. (S130 in FIG. 25)

A portion of each of the plurality of light emitting elements LE may be temporarily fixed by being embedded in the temporary adhesive layer BOL_1. For example, the contact electrode CTE (e.g., CTE1, CTE2) and the first semiconductor layer SEM1 of each of the plurality of light emitting elements LE may be fixed by being embedded in the temporary adhesive layer BOL_1.

When the temporary adhesive layer BOL_1 is a photosensitive organic layer such as a photoresist, a portion of each of the plurality of light emitting elements LE is fixed to the temporary adhesive layer BOL_1 after curing the temporary adhesive layer BOL_1 at a first temperature. Then, the temporary adhesive layer BOL_1 may be completely cured at a second temperature higher than the first temperature. The first temperature may be approximately 150 degrees Celsius, and the second temperature may be approximately 250 degrees Celsius, but the present disclosure is not limited thereto.

The plurality of light emitting elements LE may be separated from the support film SPF1 using a laser lift process.

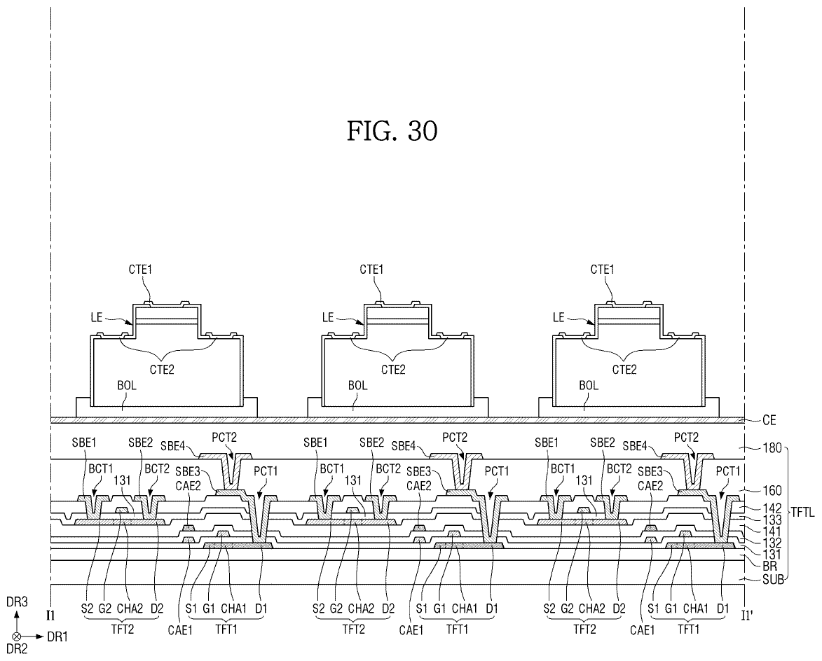

Fourth, as shown in FIG. 30, a portion of the temporary adhesive layer BOL_1 is removed to form an organic pattern layer BOL. (S140 in FIG. 25)

Using the light emitting element LE as a mask, a portion of the temporary adhesive layer BOL_1 is removed to form an organic pattern layer BOL. That is, the organic pattern layer BOL may be a remains of the temporary adhesive layer BOL_1.

If the temporary adhesive layer BOL_1 is a photosensitive organic layer such as photoresist, it may be removed through an ashing process.

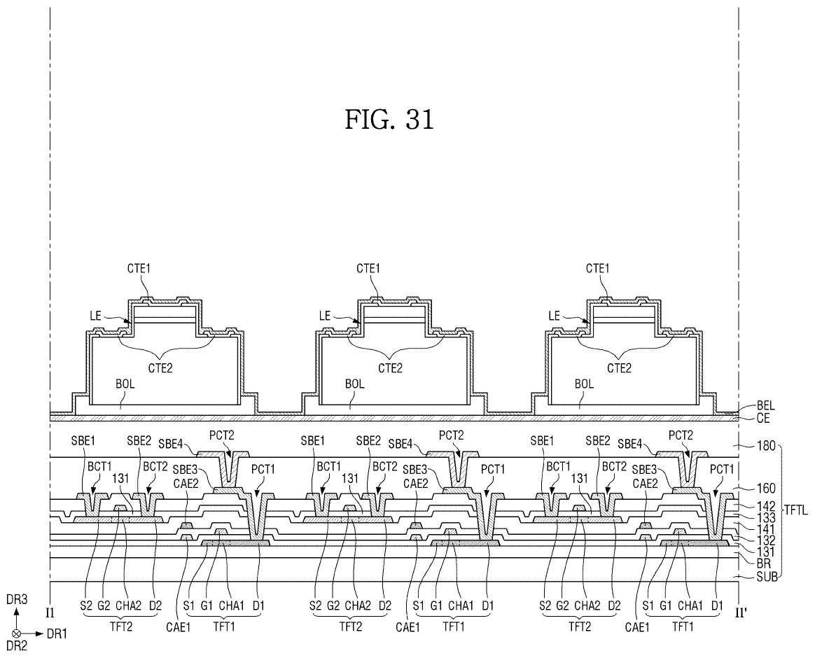

Fifth, as shown in FIGS. 31 and 32, a connection electrode BE is formed to connect the common electrode CE and the second contact electrode CTE2 of the plurality of light emitting elements LE. (S150 in FIG. 25)

To this end, a connection electrode layer BEL is first formed covering a common electrode CE, an organic pattern layer BOL, and a plurality of light emitting elements LE.

Then, a photoresist covering the entire connection electrode layer BEL is formed, the photoresist overlapping the opening of the mask is removed to expose the connection electrode layer BEL, and the exposed connection electrode layer BEL is etched to form the connection electrode BE. The photoresist may be removed by an ashing process.

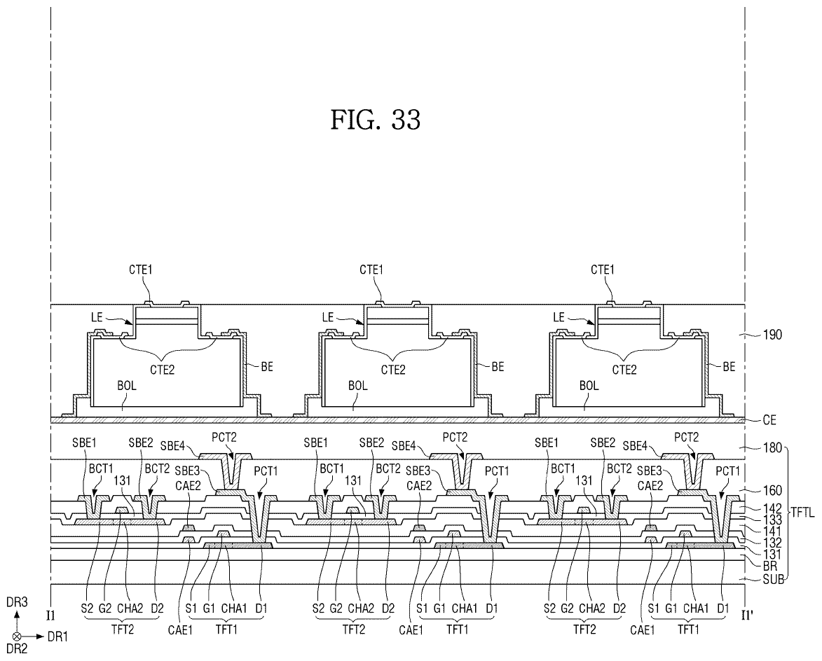

Sixth, as shown in FIG. 33, a third organic layer 190 is formed to cover a portion of the connection electrode BE and the light emitting element LE. (S160 in FIG. 25)

The third organic layer 190 may be disposed to cover a portion of the side and top surfaces of the common electrode CE and the organic pattern layer BOL, and a portion of the side surfaces of each of the plurality of light emitting elements LE.

The third organic layer 190 may be formed lower than the height of the light emitting element LE so that the first contact electrode CTE1 of the light emitting element LE is exposed.

Seventh, as shown in FIGS. 32 and 33, pixel electrodes PXE1, PXE2, and PXE3 are formed on the top surfaces of each of the first contact electrodes CTE1 of the plurality of light emitting elements LE. (S170 in FIG. 25)

For example, a pixel electrode layer PXEL covering the entirety of the first contact electrode CTE1 and the third organic layer 190 of the plurality of light emitting elements LE is formed, a photoresist covering the entirety of the pixel electrode layer PXEL is formed, the photoresist overlapping with the opening of the mask is removed to expose the pixel electrode layer, and the exposed pixel electrode layer is etched to form the pixel electrodes PXE1, PXE2, and PXE3. The photoresist may be removed by an ashing process.

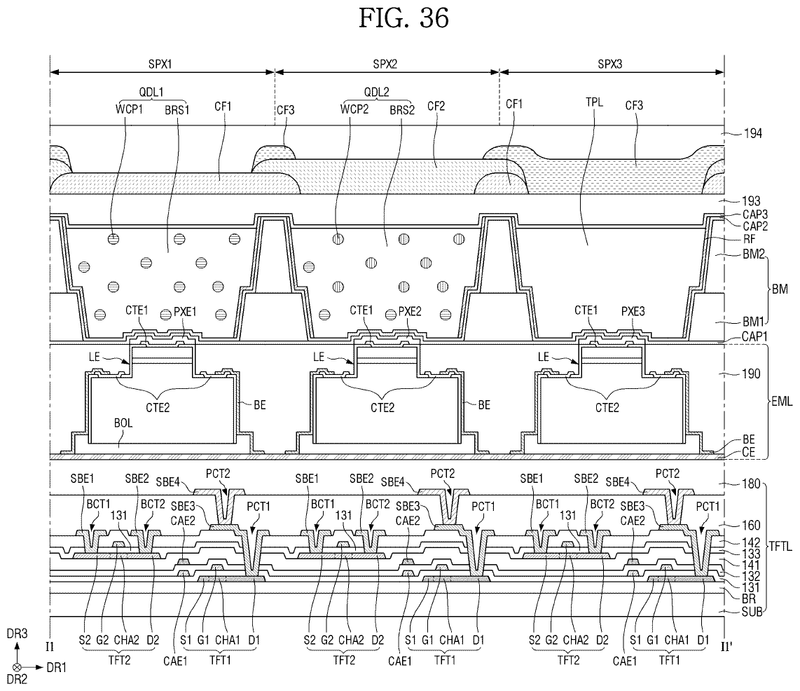

Eighth, as shown in FIG. 36, a capping layers CAP1, CAP2, CAP3, a light blocking layer BM, first and second light conversion layers QDL1 and QDL2, light transmitting layer TPL, and color filters CF1, CF2, and CF3 are formed. (S180 in FIG. 25)

The first capping layer CAP1 is formed on the common electrode CE, the first light blocking layer BM1 is formed on the first capping layer CAP1, and a second light blocking layer BM2 is formed on the first light blocking layer BM1. The first light blocking layer BM1 and the second light blocking layer BM2 may overlap the third organic layer 190 in the third direction DR3 and may not overlap the plurality of light emitting elements LE. A length in the first direction DR1 or a length in the second direction DR2 of the first light blocking layer BM1 may be greater than a length in the first direction DR1 or a length in the second direction DR2 of the second light blocking layer BM2.

Then, a second capping layer CAP2 is formed on the first capping layer CAP1 and the light blocking layer BM, and a reflective layer RF is formed on the second capping layer CAP2 disposed on a side of the first light blocking layer BM1 and a side of the second light blocking layer BM2.

Then, a first light conversion layer QDL1 is formed in the area corresponding to the first sub-pixel SPX1 in the areas partitioned from the first light blocking layer BM1 and the second light blocking layer BM2, a second light conversion layer QDL2 is formed in the area corresponding to the second sub-pixel SPX2, and a light transmitting layer TPL is formed in the area corresponding to the third sub-pixel SPX3.

Then, a third capping layer CAP3 is formed on the second capping layer CAP2, the first light conversion layer QDL1, the second light conversion layer QDL2, and the light transmitting layer TPL, and a fifth organic layer 193 is formed on the third capping layer CAP3.

Then, a plurality of color filters CF1, CF2, and CF3 are formed on the fifth organic layer 193, and a sixth organic layer 194 is formed on the plurality of color filters CF1, CF2, and CF3.

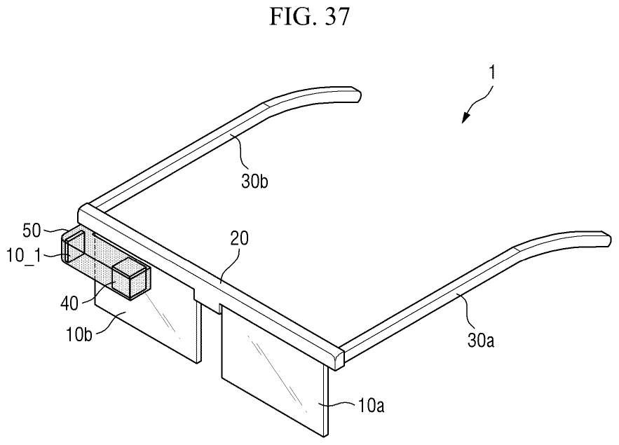

FIG. 37 is an example diagram illustrating a virtual reality device including a display device according to one or more embodiments. FIG. 37 illustrates a virtual reality device 1 in which the display device 10_1 according to one or more embodiments is used.

Referring to FIG. 37, the virtual reality device 1 according to one or more embodiments may be a device in a form of glasses. The virtual reality device 1 according to one or more embodiments may include a display device 10_1, a left-eye lens 10a, a right-eye lens 10b, a support frame 20, left and right legs 30a and 30b, a reflective member 40, and a display device housing 50.

FIG. 37 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 37, and may be applied in various forms and in various electronic devices.

The display device housing 50 may receive the display device 10_1 and the reflective member 40. An image displayed on the display device 10_1 may be reflected from the reflective member 40 and provided to a user's right eye through the right-eye lens 10b. Thus, the user may view a virtual reality image displayed on the display device 10_1 via the right eye.

FIG. 37 illustrates that the display device housing 50 is disposed at a right end of the support frame 20. However, the present disclosure is not limited thereto. For example, the display device housing 50 may be disposed at a left end of the support frame 20. In this case, the image displayed on the display device 10_1 may be reflected from the reflective member 40 and provided to the user's left eye via the left-eye lens 10a. Thus, the user may view the virtual reality image displayed on the display device 10_1 via the left eye. As another example, the display device housing 50 may be disposed at each of the left end and the right end of the support frame 20. In this case, the user may view the virtual reality image displayed on the display device 10_1 via both the left eye and the right eye.

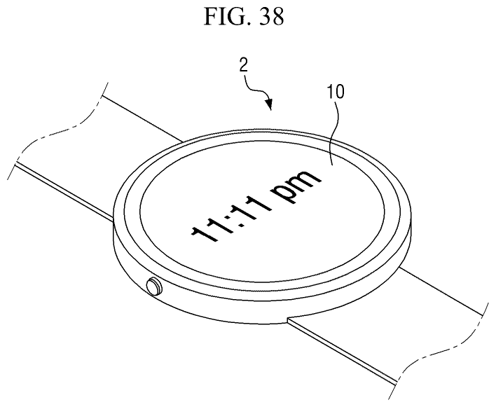

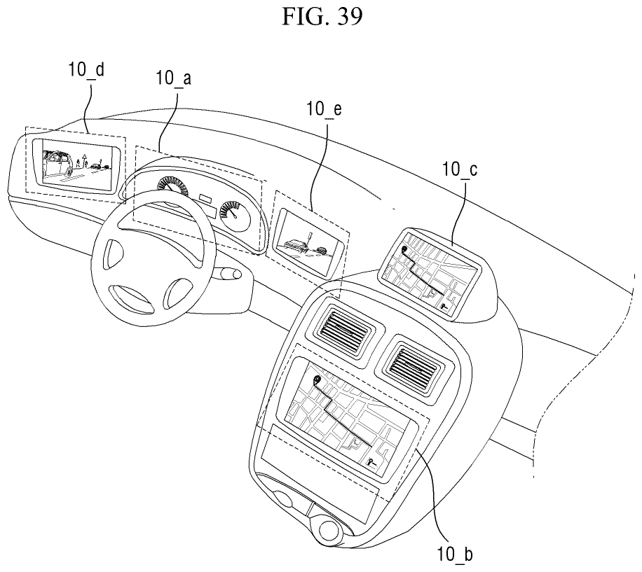

FIG. 38 is an example diagram illustrating a smart device including a display device according to one or more embodiments.

Referring to FIG. 38, a display device 10 according to one or more embodiments may be applied to a smart watch 2 as one of smart devices.

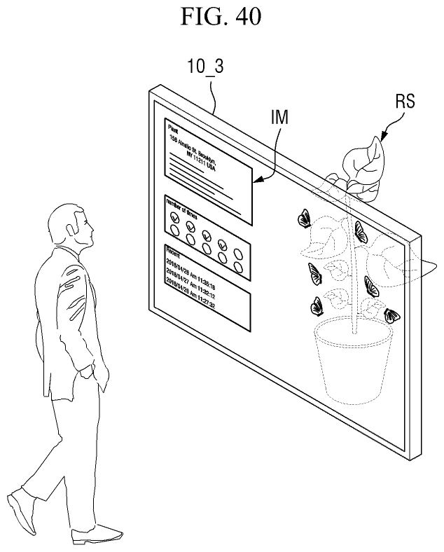

FIG. 39 is an example diagram illustrating a vehicle including a display device according to one or more embodiments. FIG. 39 illustrates a vehicle in which display devices according to one or more embodiments are used.

Referring to FIG. 39, the display devices 10_a, 10_b, and 10_c according to one or more embodiments may be applied to the dashboard of the vehicle, applied to the center fascia of the vehicle, or applied to a Center Information Display (CID) disposed on the dashboard of the vehicle. Further, each of the display devices 10_d and 10_e according to one or more embodiments may be applied to each room mirror display that replaces each of side-view mirrors of the vehicle.

FIG. 40 is an example diagram illustrating a transparent display device including a display device according to one or more embodiments.

Referring to FIG. 40, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate SUB of the display device 10 shown in FIG. 9 may include a light transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A light emitting element comprising:
a first portion comprising a first contact electrode, a first semiconductor layer, an active layer, and a second semiconductor layer arranged in a sequence;
a second portion comprising a second contact electrode, a second semiconductor layer, and a third semiconductor layer arranged in a sequence; and
a protective layer on a top portion and a side of the first portion and on a top portion and a side surface of the second portion,
wherein the first portion is on the second portion, and
wherein a diameter of the first portion is smaller than a diameter of the second portion.

2. The light emitting element of claim 1, wherein the second semiconductor layer of the second portion is connected to the second semiconductor layer of the first portion.

3. The light emitting element of claim 2, wherein the first portion and the second portion have a cylindrical shape, and
wherein the second portion is around the first portion in a plane view.

4. The light emitting element of claim 3, wherein the second contact electrode is around the first portion in a plan view.

5. The light emitting element of claim 2, wherein the first portion and the second portion have a rectangular parallelepiped shape,
wherein one side of the first portion and one side of the second portion are aligned and coincide with each other.

6. A display device comprising:
a substrate;
a common electrode on the substrate;
an organic pattern layer on the common electrode;
a light emitting element on the organic pattern layer and having a first contact electrode and a second contact electrode;
a pixel electrode on the first contact electrode; and
a connection electrode connecting the second contact electrode and the common electrode,
wherein the light emitting element comprises:
a first portion comprising the first contact electrode, a first semiconductor layer, an active layer, and a second semiconductor layer;
a second portion comprising the second contact electrode, a second semiconductor layer, and a third semiconductor layer; and
a protective layer on a top portion and a side of the first portion and a top portion and a side of the second portion,
wherein the first portion is on the second portion, and
wherein a diameter of the first portion is smaller than a diameter of the second portion.

7. The display device of claim 6, further comprising an organic layer covering a top surface of the connection electrode and a side surface of the light emitting element.

8. The display device of claim 6, wherein the connection electrode has a higher reflectivity than the pixel electrode.

9. The display device of claim 8, wherein the common electrode and the connection electrode comprise a metal material,
wherein the pixel electrode comprises a transparent conductive oxide.

10. The display device of claim 9, wherein the common electrode is a common layer that is common to a plurality of sub-pixels.

11. The display device of claim 6, wherein the second semiconductor layer of the second portion is connected to the second semiconductor layer of the first portion.

12. The display device of claim 11, wherein the first portion and the second portion have a cylindrical shape,
the second portion is around the first portion in a plan view, and
the second contact electrode is around the first portion in a plan view.

13. The display device of claim 12, further comprising:
a first organic layer covering the second contact electrode,
a second organic layer on the first organic layer,
a function layer between the first organic layer and the second organic layer,
wherein the function layer comprises at least one of a protective layer comprising an inorganic film or a reflective layer comprising a highly reflective material.

14. The display device of claim 11, wherein the first portion and the second portion have a rectangular parallelepiped shape,
wherein one side of the first portion and one side of the second portion are aligned and coincide with each other.

15. A method of manufacturing a light emitting element comprising:
forming a plurality of semiconductor material layers on a base substrate;
etching the plurality of semiconductor material layers to form a light emitting element comprising a third semiconductor layer, a second semiconductor layer, an active layer, and a first semiconductor layer;
forming a first portion and a second portion of the light emitting element by etching a portion of the first semiconductor layer, the active layer, and the second semiconductor layer;
forming a protective layer on a top portion and a side of the first portion and on a top portion and a side of the second portion; and
forming a first contact electrode on a top of the first portion and forming a second contact electrode on a top of the second portion,
wherein the second portion is on the first portion, and a diameter of the first portion is smaller than a diameter of the second portion.

16. The method of claim 15, in the forming the first portion and the second portion,
wherein a periphery of each of the first semiconductor layer, the active layer, and the second semiconductor layer is etched so that the first portion is at a center of the second portion in a plan view, so that a top surface of the first portion exposes the second semiconductor layer.

17. The method of claim 16, wherein in the forming the first contact electrode on the top surface of the first portion, and forming the second contact electrode on the top surface of the second portion,
wherein the first contact electrode is formed to contact the first semiconductor layer of the first portion,
wherein the second contact electrode is formed to contact the second semiconductor layer of the second portion.

18. A method of manufacturing a display device comprising:
forming a thin film transistor layer and a common electrode on a substrate;
forming a temporary adhesive layer on the common electrode and aligning light emitting elements;
fixing a light emitting element from among the light emitting elements on the temporary adhesive layer and removing a portion of the temporary adhesive layer to form an organic pattern layer;
forming a connection electrode connecting the common electrode and a second contact electrode of the light emitting element;
forming an organic layer covering a portion of the connection electrode and the light emitting element; and
forming a pixel electrode on a first contact electrode of the light emitting element,
wherein the light emitting element comprises:
a first portion comprising the first contact electrode, a first semiconductor layer, an active layer, and a second semiconductor layer arranged in a sequence,
a second portion comprising the second contact electrode, a second semiconductor layer, and a third semiconductor layer arranged in a sequence,
wherein the first portion is on the second portion,
wherein a diameter of the first portion is smaller than a diameter of the second portion.

19. The method of claim 18, the fixing the light emitting element to the organic pattern layer further comprises:
curing the organic pattern layer at a first temperature;
inserting a portion of the light emitting element into the organic pattern layer; and
curing the organic pattern layer at a second temperature higher than the first temperature.

20. The method of claim 18, further comprising:
forming a light blocking layer on a via layer fixed to the organic pattern layer and defining a light emitting area;
forming a first wavelength conversion layer in a region corresponding to a first sub-pixel, forming a second wavelength conversion layer in a region corresponding to a second sub-pixel, and forming a light transmitting layer in a region corresponding to a third sub-pixel from among the regions partitioned by the light blocking layer; and
forming a first color filter on the first wavelength conversion layer, forming a second color filter on the second wavelength conversion layer, and forming a third color filter on the light transmitting layer.
